(19) United States
(12) Patent Application Publication
(10) Pub. No.: US 2025/0063886 A1
(43) Pub. Date: Feb. 20, 2025

(54) DISPLAY DEVICE AND METHOD FOR MANUFACTURING THE SAME

(71) Applicant: Samsung Display Co., LTD., Yongin-si (KR)

(72) Inventor: HEUNGGYU KIM, Yongin-si (KR)

(21) Appl. No.: 18/735,683

(22) Filed: Jun. 6, 2024

(30) Foreign Application Priority Data
Aug. 16, 2023 (KR) 10-2023-0106734

(51) Int. Cl. H10K 50/844; H10K 50/115; H10K 50/15; H10K 50/16; H10K 59/122; H10K 59/35; H10K 59/70; H10K 71/13

(52) U.S. Cl. CPC H10K 50/844; H10K 50/115; H10K 50/156; H10K 50/166; H10K 59/122; H10K 59/35; H10K 59/70; H10K 71/135

(57) ABSTRACT

Provided is a display device including a base layer, a circuit layer, a pixel defining layer having a plurality of pixel openings defined therein, and a plurality of light emitting elements each including a hole transport region, an emission layer, and an electron transport region which are sequentially stacked, and on the circuit layer, wherein the light emitting elements include an inorganic light emitting element including an inorganic luminous body in the emission layer, and an organic light emitting element including an organic luminous body in the emission layer, and the inorganic light emitting element or the organic light emitting element includes a protection layer between the emission layer and the electron transport region and including a polar polymer, thereby exhibiting improved luminous efficiency.

### CROSS-REFERENCE TO RELATED APPLICATIONS

The present application claims priority to and the benefit of Korean Patent Application No. 10-2023-0106734, filed on Aug. 16, 2023, in the Korean Intellectual Property Office, the entire content of which is hereby incorporated by reference.

### BACKGROUND

### 1. Field

Embodiments of the present disclosure herein relate to a display device and a method for manufacturing the same, and for example, to a display device including both an inorganic light emitting element and an organic light emitting element and a method for manufacturing the same.

### 2. Description of the Related Art

Various types of display devices used for multimedia electronic devices such as televisions, mobile phones, tablets, navigation systems, and game consoles are being developed. Such display devices include so-called self-luminescent light emitting elements configured to provide a display by causing light emitting materials to emit light.

The light emitting elements include inorganic light emitting elements including inorganic light emitting materials such as quantum dots in emission layers, and/or organic light emitting elements including organic light emitting materials in emission layers. The display devices may include both the inorganic light emitting elements and the organic light emitting elements, considering optical properties and characteristics of emission layer materials. However, the inorganic light emitting elements and the organic light emitting elements should be optimized or improved in structures thereof for improving the efficiency of each light emitting element.

### SUMMARY

Embodiments of the present disclosure provide a display device having excellent luminous efficiency by improving interface properties between an emission layer and an electron transport region.

Embodiments of the present disclosure also provide a method for manufacturing a display device having excellent processability by providing the same electron transport layer on an emission layer having different characteristics when each functional layer of a light emitting element is formed through inkjet printing.

An embodiment of the present disclosure provides a display device including a base layer, a circuit layer on the base layer, a pixel defining layer on the circuit layer and having a plurality of pixel openings defined therein, and a plurality of light emitting elements each including a hole transport region, an emission layer, and an electron transport region which are sequentially stacked, and on the circuit layer, wherein the light emitting elements include an inorganic light emitting element including an inorganic luminous body in the emission layer, and an organic light emitting element including an organic luminous body in the emission layer, and the inorganic light emitting element or the organic light emitting element includes a protection layer between the emission layer and the electron transport region and includes a polar polymer.

In an embodiment, the protection layer may include poly(ethylene glycol), poly(4-vinylpyridine), polyvinylpyrrolidone, and/or polyethylenimine.

In an embodiment, the polar polymer may be soluble in a polar organic solvent.

In an embodiment, the polar organic solvent may be dimethyl sulfoxide, ethylene glycol, and/or an ether-based solvent.

In an embodiment, the protection layer may have a thickness of about 50 Å to about 200 Å, and the thickness of the protection layer may be a distance from an uppermost portion of the emission layer of the inorganic light emitting element or the organic light emitting element including the protection layer to the electron transport region.

In an embodiment, the electron transport region may include an inorganic electron transport material, and the organic light emitting element may include the protection layer.

In an embodiment, the electron transport region may include an electron transport layer including the inorganic electron transport material, and, in the inorganic light emitting element, the electron transport layer may be directly on the emission layer, and in the organic light emitting element, the protection layer may be directly between the electron transport layer and the emission layer.

In an embodiment, the electron transport region may include an organic electron transport material, and the inorganic light emitting element may include the protection layer.

In an embodiment, the electron transport region may include an electron transport layer including the organic electron transport material, and, in the organic light emitting element, the electron transport layer may be directly on the emission layer, and in the inorganic light emitting element, the protection layer may be directly between the electron transport layer and the emission layer.

In an embodiment, the inorganic luminous body may include a plurality of quantum dots, and the protection layer of the inorganic light emitting element may be in an upper portion of the emission layer and may be provided to permeate between the quantum dots.

In an embodiment, the hole transport region, the emission layer, and the electron transport region may be stacked and provided in each of the pixel openings, and the hole transport regions included in the inorganic light emitting element and the organic light emitting element may be the same, and the electron transport regions included in the inorganic light emitting element and the organic light emitting element may be the same.

In an embodiment of the present disclosure, a display device including a red light emitting region, a green light emitting region, and a blue light emitting region which are distinct from one another when viewed in a plane (e.g., in a plan view) respectively includes a base layer, a circuit layer on the base layer, and a display layer including a red light emitting element provided corresponding to the red light emitting region, a green light emitting element provided corresponding to the green light emitting region, and a blue light emitting element provided corresponding to the blue light emitting region and on the circuit layer, wherein the red light emitting element, the green light emitting element, and the blue light emitting element each include a hole transport region, an emission layer, and an electron transport region which are sequentially stacked, one or two of the light emitting elements selected from the red light emitting element, the green light emitting element, and the blue light emitting element are inorganic light emitting elements including quantum dots in the emission layer, and the other light emitting elements are organic light emitting elements including an organic light emitting material in the emission layer, and the inorganic light emitting element or the organic light emitting element includes a protection layer between the emission layer and the electron transport region and includes a polar polymer.

In an embodiment, the protection layer may include poly(ethylene glycol), poly(4-vinylpyridine), polyvinylpyrrolidone, and/or polyethylenimine.

In an embodiment, the electron transport region of the inorganic light emitting element and the organic light emitting element may include an inorganic electron transport layer including an inorganic electron transport material, and the protection layer may be directly between the emission layer of the organic light emitting element and the inorganic electron transport layer.

In an embodiment, the electron transport region of the inorganic light emitting element and the organic light emitting element may include an organic electron transport layer including an organic electron transport material, and the protection layer may be directly between the emission layer of the inorganic light emitting element and the organic electron transport layer.

In an embodiment, the red light emitting element and the green light emitting element may be the inorganic light emitting element, and the blue light emitting element may be the organic light emitting element.

In an embodiment of the present disclosure, a method for manufacturing a display device includes forming a circuit layer on a base layer, and forming a display layer including a pixel defining layer having a plurality of pixel openings defined on the circuit layer, and an inorganic light emitting element and an organic light emitting element which are separated by the pixel defining layer, wherein the forming of the display layer includes sequentially providing a hole transport region, an inorganic emission layer including quantum dots, and an electron transport region in at least one of the pixel openings through a method of inkjet printing to form the inorganic light emitting element, and sequentially providing the hole transport region, an organic emission layer including an organic light emitting material, and the electron transport region in the other pixel openings through a method of inkjet printing to form the organic light emitting element, and the forming of the inorganic light emitting element or the forming of the organic light emitting element includes providing a protection layer ink between the inorganic emission layer and the electron transport region or between the organic emission layer and the electron transport region through a method of inkjet printing to form a protection layer, and the protection layer ink includes a polar polymer and a polar organic solvent.

In an embodiment, the polar polymer may be poly(ethylene glycol), poly(4-vinylpyridine), polyvinylpyrrolidone, and/or polyethylenimine.

In an embodiment, the polar organic solvent may be dimethyl sulfoxide, ethylene glycol, and/or an ether-based solvent.

In an embodiment, the electron transport region formed in the forming of the inorganic light emitting element and the forming the organic light emitting element may include an electron transport layer formed using the same electron transport material.

In an embodiment, the electron transport material may include an organic electron transport material, and the forming of the inorganic light emitting element may include forming the protection layer between the inorganic emission layer and the electron transport layer.

In an embodiment, the electron transport material may include an inorganic electron transport material, and the forming of the organic light emitting element may include forming the protection layer between the organic emission layer and the electron transport layer.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a perspective view showing a display device of an embodiment;

FIG. 2 is a cross-sectional view showing a portion corresponding to line I-I′ of FIG. 1;

FIG. 3 is a cross-sectional view showing a portion corresponding to line II-II′ of FIG. 1;

FIG. 4A is a cross-sectional view of a light emitting element according to an embodiment;

FIG. 4B is a cross-sectional view of a light emitting element according to an embodiment;

FIG. 4C is a cross-sectional view of a light emitting element according to an embodiment;

FIG. 5A is a cross-sectional view of a light emitting element according to an embodiment;

FIG. 5B is a cross-sectional view of a light emitting element according to an embodiment;

FIG. 5C is a cross-sectional view of a light emitting element according to an embodiment;

FIG. 6 is a cross-sectional view showing a display device of an embodiment;

FIG. 7A is a cross-sectional view showing a portion of a display panel according to an embodiment;

FIG. 7B is a cross-sectional view showing a portion of a display panel according to an embodiment;

FIG. 8A is a cross-sectional view showing a portion of a display panel according to an embodiment;

FIG. 8B is a cross-sectional view showing a portion of a display panel according to an embodiment; and

FIGS. 9A-9E are each cross-sectional views showing a portion of a method for manufacturing a display device according to an embodiment.

### DETAILED DESCRIPTION

The subject matter of the present disclosure may be modified in many alternate forms, and thus example embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

It will be understood that when an element (or a region, a layer, a portion, or the like) is referred to as “being on”, “connected to” or “coupled to” another element, it may be directly on, connected or coupled to the other element, or intervening elements may be therebetween.

Like reference numerals refer to like elements. In addition, in the drawings, the thickness, the ratio, and the dimensions of elements may be exaggerated for an effective description of technical contents. The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the spirit or scope of the present disclosure. The singular forms are intended to include the plural forms as well, unless the context clearly indicates otherwise.

Also, terms of “below”, “on lower side”, “above”, “on upper side”, or the like may be used to describe the relationships of the components shown in the drawings. The terms are used as a relative concept and are described with reference to the direction indicated in the drawings, but the present disclosure is not limited thereto.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, the term “Group” refers to a group of the IUPAC periodic table of elements.

As used herein, “Group II” may include Group IIA elements and Group IIB elements. For example, the Group II elements may be magnesium (Mg) and/or zinc (Zn), but are not limited thereto.

As used herein, “Group III” may include Group IIIA elements and Group IIIB elements. For example, the Group III elements may be aluminum (AI), indium (In), gallium (Ga), and/or titanium (Ti), but are not limited thereto.

As used herein, “Group V” may include Group VA elements and Group VB elements. For example, the Group V elements may be phosphorus (P), arsenic (As), and/or antimony (Sb), but are not limited thereto.

As used herein, “Group VI” may include Group VIA elements and Group VIB elements. For example, the Group VI elements may be oxygen (O), sulfur(S), selenium (Se) and/or tellurium (Te), but are not limited thereto.

Unless otherwise defined, all terms (including technical and scientific terms) used herein have the same meaning as commonly understood by one of ordinary skill in the art to which the present disclosure pertains. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the present disclosure and a method for manufacturing the display device of an embodiment will be described with reference to the accompanying drawings.

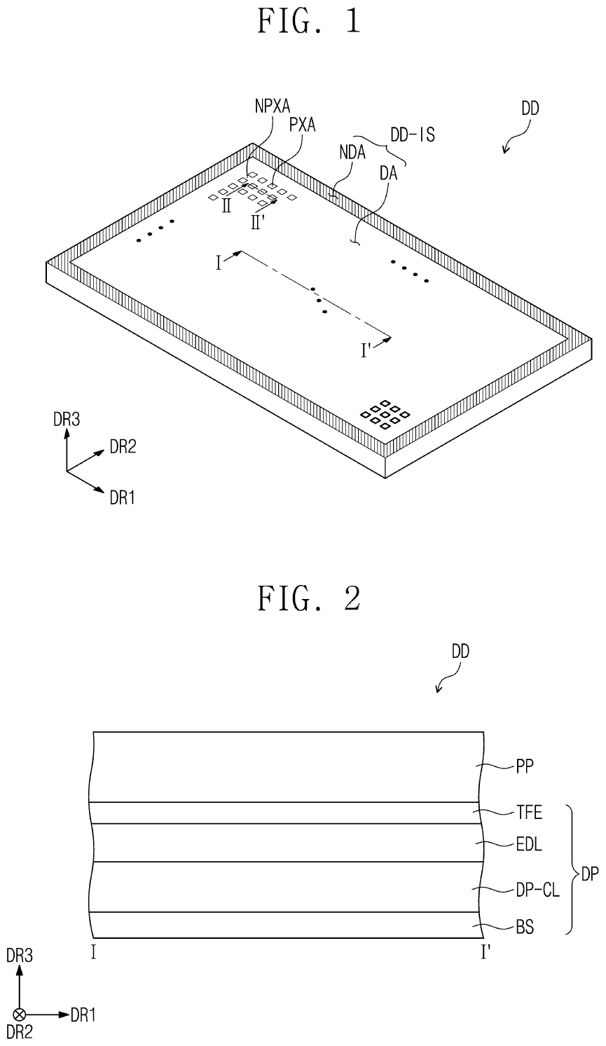

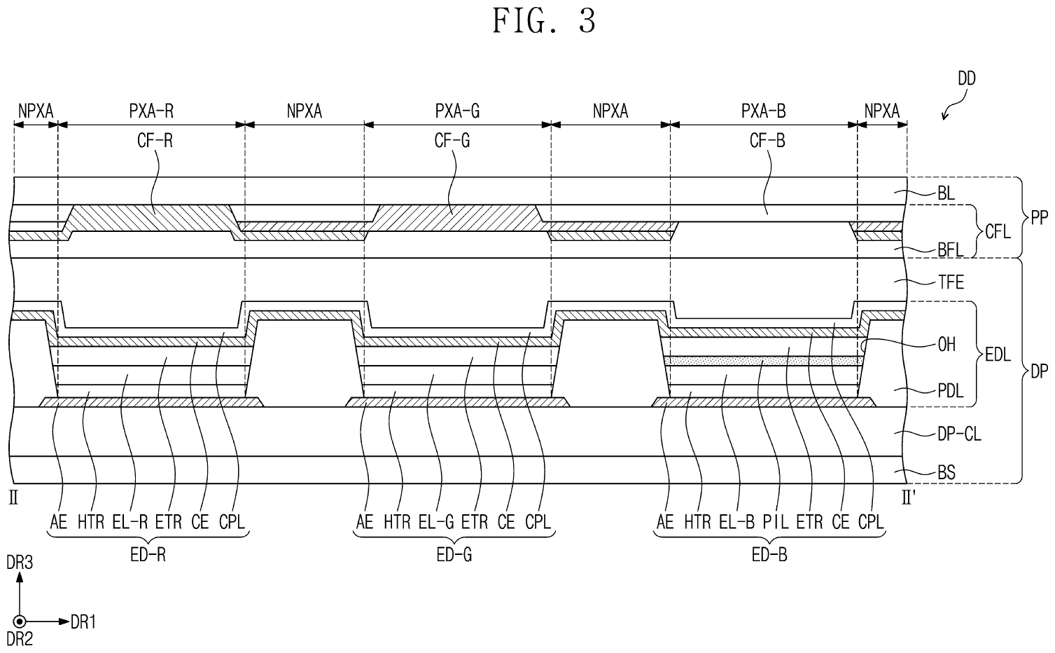

FIG. 1 is a perspective view showing a display device according to an embodiment. FIG. 2 is a cross-sectional view of a display device according to an embodiment. FIG. 3 is a cross-sectional view showing a portion of a display device according to an embodiment in more detail. FIG. 2 is a cross-sectional view corresponding to line I-I′ of FIG. 1, and FIG. 3 is a cross-sectional view corresponding to line II-II′ of FIG. 1.

A display device DD may be a device activated according to electrical signals. For example, the display device DD may be a large-sized device such as televisions, monitors, and/or outdoor billboards. In addition, the display device DD may be a small- and/or medium-sized device such as personal computers, laptop computers, personal digital terminals, car navigation systems, game consoles, smart phones, tablets, and/or cameras. In addition, these devices are merely provided as embodiments, and other electronic devices may be employed as long as not departing from the spirit or scope of the present disclosure.

The display device DD may display images (and/or videos) through a display surface DD-IS. The display device DD may include a plurality of light emitting regions PXA and a non-light emitting region NPXA. The display surface DD-IS may be parallel to a plane defined by a first direction DR1 and a second direction DR2. The display surface DD-IS may include a display region DA and a non-display region NDA. The plurality of light emitting regions PXA may be in the display region DA. The light emitting regions PXA may be referred to as pixel regions.

The non-display region NDA may be defined along an edge of the display surface DD-IS. The non-display region NDA may surround the display region DA. However, embodiments of the present disclosure are not limited thereto, and the non-display region NDA may not be provided, or the non-display region NDA may be disposed only on one side of the display region DA.

FIG. 1 shows the display device DD provided with the flat display surface DD-IS, but embodiments of the present disclosure are not limited thereto. The display device DD may include a curved display surface and/or a three-dimensional display surface. The three-dimensional display surface may include a plurality of display regions indicating different directions.

FIG. 1 and the following drawings show first to third directional axes DR1 to DR3, and directions indicated by the first to third directional axes DR1, DR2, and DR3 described herein are relative concepts, and may thus be changed to other directions. In addition, the directions indicated by the first to third directional axes DR1, DR2, and DR3 may be described as first to third directions, and the same reference numerals may be used. The first directional axis DR1 and the second directional axis DR2 herein may be perpendicular to each other, and a third directional axis DR3 may be a normal direction to a plane defined by the first directional axis DR1 and the second directional axis DR2. Herein, the term ‘plane’ refers to a plane defined by the first directional axis DR1 and the second directional axis DR2, and the term ‘cross-section’ refers to a plane perpendicular to the plane defined by the first directional axis DR1 and the second directional axis DR2 and parallel to the third directional axis DR3. A thickness direction of the display device DD may be parallel to the third direction DR3 which is a normal direction with respect to the plane defined by the first direction DR1 and the second direction DR2.

An upper surface (or a front surface) and a lower surface (or a rear surface) of members constituting the display device DD herein may be defined with respect to the third direction DR3. In some embodiments, among the two surfaces facing in the third direction DR3 in one member, the surface relatively adjacent to the display surface DD-IS may be defined as a front surface (or an upper surface), and the surface relatively spaced apart from the display surface DD-IS may be defined as a rear surface (or a lower surface). In addition, herein, an upper portion (or an upper side) and a lower portion (or a lower side) may be defined with respect to the third direction DR3, and the upper portion (or upper side) may be defined as a direction closer toward the display surface DD-IS, and the lower portion (or lower side) may be defined as a direction away from the display surface DD-IS.

Herein, when a component is “directly disposed/directly formed” on another component, it indicates that a third component is not between one component and another component. For example, when a component is “directly placed/directly formed” on another component, it indicates that a component is in “contact” with another component.

Referring to FIGS. 2-3, the display device DD may include a display panel DP and an optical member PP on the display panel DP. The display panel DP may include a display layer EDL. The display panel DP may include a base layer BS, a circuit layer DP-CL on the base layer, and a display layer EDL on the circuit layer DP-CL. The display layer EDL may include light emitting elements ED-R, ED-G, and ED-B. In addition, the display panel DP may include an encapsulation layer TFE on the display layer EDL. The encapsulation layer TFE may be directly on the display layer EDL or may be bonded to the display layer EDL through a separate member.

The display panel DP may be configured to substantially generate images. In the display device DD of an embodiment, the display panel DP may be a light emitting display panel. In an embodiment, the display panel DP may include both an inorganic light emitting element including an inorganic luminous body such as quantum dots, and an organic light emitting element including an organic luminous body.

The optical member PP may be on the display panel DP to control reflected light in the display panel DP by external light.

Referring to FIGS. 1-3, the plurality of light emitting regions PXA may be in the display region DA of the display device DD of an embodiment. The plurality of light emitting regions PXA may each be a region where light generated from each of the light emitting elements ED-R, ED-G, and ED-B is emitted.

The light emitting regions PXA in the display device DD according to an embodiment may be arranged in the form of a stripe. Referring to FIG. 1, the plurality of light emitting regions PXA may be aligned along the first directional axis DR1 or the second directional axis DR2. However, embodiments of the present disclosure are not limited thereto, and the light emitting regions PXA may be arranged in the form of a PENTILE® arrangement structure (e.g., an RGBG matrix, RGBG structure, or RGBG matrix structure) or a DIAMOND PIXEL™ arrangement structure, but the present disclosure is not limited thereto. PENTILE® is a duly registered trademark of Samsung Display Co., Ltd.

In addition, the light emitting regions PXA are shown to have areas of similar size in FIG. 1 and the like, but embodiments of the present disclosure are not limited thereto, and the light emitting regions PXA may have areas of different sizes according to the wavelength range of emitted light.

The light emitting regions PXA may include first to third light emitting regions PXA-R, PXA-G, and PXA-B. The display device DD may include the plurality of light emitting regions PXA-R, PXA-G, and PXA-B, which are in a repeated arrangement throughout the display region DA. The display device DD of an embodiment may include first to third light emitting regions PXA-R, PXA-G, and PXA-B, which are distinct from one another. In addition, the display device DD may include a non-light emitting region NPXA provided around the first to third light emitting region PXA-R, PXA-G, and PXA-R. The non-light emitting region NPXA sets boundaries between the first to third pixel regions PXA-R, PXA-G, and PXA-B. The non-light emitting region NPXA may surround the first to third light emitting region PXA-R, PXA-G, and PXA-R. A structure that prevents or reduces color mixing between the first to third light emitting regions PXA-R, PXA-G, and PXA-B, for example, a pixel defining layer PDL may be in the non-light emitting region NPXA.

The first to third light emitting regions PXA-R, PXA-G, and PXA-B may each be a region separated by the pixel defining layer PDL. The non-light emitting regions NPXA may be regions between neighboring the first to third light emitting regions PXA-R, PXA-G, and PXA-B, and may correspond to the pixel defining layer PDL.

The first to third light emitting regions PXA-R, PXA-G, and PXA-B may each be a region that emits light generated from each of the first to third light emitting elements ED-1, ED-2, and ED-3. The first to third light emitting regions PXA-R, PXA-G, and PXA-B may be spaced apart from one another when viewed on a plane (e.g., in a plan view).

In some embodiments, the first to third light emitting regions PXA-R, PXA-G, and PXA-B may each correspond to a pixel. The pixel defining layer PDL may separate the first to third light emitting elements ED-1, ED-2, and ED-3. Emission layers EML-R, EML-G, and EML-B of the first to third light emitting elements ED-1, ED-2 and ED-3 may be provided and separated in an opening OH defined by the pixel defining layer PDL.

The pixel defining layer PDL may be formed of a polymer resin. For example, the pixel defining layer PDL may be formed including a polyacrylate-based resin and/or a polyimide-based resin. In addition, the pixel defining layer PDL may be formed by further including an inorganic material in addition to the polymer resin. In some embodiments, the pixel defining layer PDL may be formed including a light absorbing material, and/or may be formed including a black pigment and/or a black dye. The pixel defining layer PDL formed including a black pigment and/or a black dye may be a black pixel defining layer. When forming the pixel defining layer PDL, carbon black may be used as a black pigment and/or a black dye, but embodiments of the present disclosure are not limited thereto.

In addition, the pixel defining layer PDL may be formed of an inorganic material. For example, the pixel defining layer PDL may be formed of silicon nitride (SiNx), silicon oxide (SiOx), silicon oxynitride (SiOxNy), and/or the like.

The first to third light emitting regions PXA-R, PXA-G, and PXA-B may be divided according to the color of light generated from the first to third light emitting elements ED-1, ED-2 and ED-3. In the display device DD of an embodiment shown in FIG. 3, three light emitting regions PXA-R, PXA-G, and PXA-B, which emit red light, green light, and blue light, are shown as an example. For example, in the display device DD of an embodiment, the first light emitting region PXA-R may be a red light emitting region, the second light emitting region PXA-G may be a green light emitting region, and the third light emitting region PXA-B may be a blue light emitting region.

In the display device DD according to an embodiment, light emitting elements ED-R, ED-G, ED-B may emit light having different wavelength ranges. For example, in the display device DD of an embodiment, the first light emitting element ED-R may correspond to a red light emitting element that emits red light, the second light emitting element ED-G may correspond to a green light emitting element that emits green light, and the third light emitting element ED-B may correspond to a blue light emitting element that emits blue light. In some embodiments, the red light emitting region PXA-R, the green light emitting region PXA-G, and the blue light emitting region PXA-B of the display device DD may correspond to the first light emitting element ED-R, the second light emitting element ED-G, and the third light emitting element ED-B, respectively.

In FIG. 3, three distinct light emitting regions PXA-R, PXA-G, and PXA-B are shown, but embodiments of the present disclosure are not limited thereto, and the display device DD of an embodiment may include four or more light emitting regions having different light emitting characteristics.

In the display panel DP, the base layer BS may be a member providing a base surface in which the display layer EDL is provided. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In an embodiment, the circuit layer DP-CL may be on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the light emitting elements ED-R, ED-G, and ED-B of the display layer EDL.

The encapsulation layer TFE may cover the light emitting elements ED-R, ED-G, and ED-B. The encapsulation layer TFE may seal the display layer EDL. The encapsulation layer TFE may be a thin film encapsulation layer. The encapsulation layer TFE may be a single layer or a laminated layer of a plurality of layers. The encapsulation layer TFE includes at least one insulating layer (e.g., an electrically insulating layer). The encapsulation layer TFE according to an embodiment may include at least one inorganic film (hereinafter, an encapsulation inorganic film). In addition, the encapsulation layer TFE according to an embodiment may include at least one organic film (hereinafter, an encapsulation organic film) and at least one encapsulation inorganic film.

The encapsulation inorganic film protects the display layer EDL from moisture/oxygen, and the encapsulation organic film protects the display layer EDL from foreign substances such as dust particles. The encapsulation inorganic film may include silicon nitride, silicon oxy nitride, silicon oxide, titanium oxide, aluminum oxide, and/or the like, but is not particularly limited thereto. The encapsulation organic film may include an acrylic compound, an epoxy-based compound, and/or the like. The encapsulation organic film may include a photopolymerizable organic material, and is not particularly limited.

The optical member PP may be a reflection reduction layer reducing reflectance by external light. For example, the optical member PP may include a polarizing film including a phase retarder and/or a polarizer, multi-layered reflection layers that induces destructive interference of reflected light, and/or color filters corresponding to the pixel arrangement and light emitting color of the display panel DP. When the optical member PP includes the color filters, the color filters may be provided in consideration of the light emitting colors of pixels included in the display panel DP. In addition, in an embodiment, the optical member PP may not be provided.

In an embodiment, the optical member PP may include a base substrate BL and a color filter layer CFL.

The base substrate BL may be a member providing a base surface on which the color filter layer CFL is provided. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer.

The color filter layer CFL may include filters CF-R, CF-G, and CF-B. The color filter layer CFL may include first to third filters CF-R, CF-G, and CF-B. The first to third filters CF-R, CF-G, and CF-B may each correspond to the first to third light emitting elements ED-R, ED-G, and ED-B. For example, the first filter CF-R may be a red filter, the second filter CF-G may be a green filter, and the third filter CF-B may be a blue filter. The first to third filters CF-R, CF-G, and CF-B may each correspond to each of the first to third pixel regions PXA-R, PXA-G, and PXA-B.

In some embodiments, the plurality of filters CF-R, CF-G, and CF-B that transmit different light may overlap in areas corresponding to the non-light emitting region NPXA between the light emitting regions PXA-R, PXA-G, and PXA-B. The plurality of filters CF-R, CF-G, and CF-B may overlap in the third direction DR3, which is the thickness direction, to separate boundaries between the adjacent light emitting regions PXA-R, PXA-G, and PXA-B. Accordingly, the effect of blocking or reducing external light increases to serve as the same function as a black matrix. The overlapping structure of the plurality of filters CF-R, CF-G, and CF-B may serve to prevent or reducing color mixing.

The first to third filters CF-R, CF-G, and CF-B may each include a polymer photosensitive resin and a pigment and/or a dye. The first filter CF-R may include a red pigment or a red dye, the second filter CF-G may include a green pigment and/or a green dye, and the third filter CF-B may include a blue pigment or a blue dye. However, embodiments of the present disclosure are not limited thereto, and the third filter CF-B may not include a pigment or a dye. The third filter CF-B may include a polymer photosensitive resin, but not include a pigment or a dye. The third filter CF-B may be transparent. The third filter CF-B may be formed of a transparent photosensitive resin.

The color filter layer CFL may further include a buffer layer BFL. For example, the buffer layer BFL may be a protection layer protecting the first to third filters CF-R, CF-G, and CF-B. The buffer layer BFL may be an inorganic material layer including at least one inorganic material among silicon nitride, silicon oxide, and silicon oxynitride. The buffer layer BFL may be formed of a single layer or a plurality of layers.

In addition, the first filter CF-R and the second filter CF-G may be yellow filters. The first filter CF-R and the second filter CF-G may not be separated from each other and may be provided as a single body.

In some embodiments, the color filter layer CFL may further include a light blocking unit. The light blocking unit may be a black matrix. The light blocking unit may be formed including an organic light blocking material and/or an inorganic light blocking material, both including a black pigment and/or a black dye. The light blocking unit may prevent or reduce light leakage, and separate boundaries between the adjacent filters CF-R, CF-G, and CF-B.

In some embodiments, unlike what is shown in FIG. 3 and the like, the optical member PP of the display device DD of an embodiment may not include the color filter layer CFL.

In the display device DD of an embodiment, each of the first to third light emitting elements ED-R, ED-G, and ED-B may include a first electrode AE, a hole transport region HTR, an emission layer EL-R, EL-G, and EL-B, an electron transport region ETR, and a second electrode CE. In some embodiments, the light emitting elements ED-R, ED-G, and ED-B may each include a capping layer CPL on the second electrode CE.

The first electrode AE may be exposed in a pixel opening OH of the pixel defining layer PDL. The first electrode AE has conductivity (e.g., electrical conductivity). The first electrode AE may be formed of a metal material, a metal alloy and/or a conductive compound. The first electrode AE may be an anode or cathode. In addition, the first electrode AE may be a pixel electrode. However, embodiments of the present disclosure are not limited thereto.

The second electrode CE may be on the first electrode AE. The second electrode CE may be a cathode or an anode. In an embodiment, when the first electrode AE is an anode, the second electrode CE may be a cathode, and when the first electrode AE is a cathode, the second electrode CE may be an anode. The second electrode CE may be a common electrode. However, embodiments of the present disclosure are not limited thereto.

The hole transport region HTR may be between the first electrode AE and the emission layers EL-R, EL-G, and EL-B, and the electron transport region ETR may be between the emission layers EL-R, EL-G, and EL-B and the second electrodes CE.

In an embodiment shown in FIG. 3, the hole transport region HTR, the emission layers EL-R, EL-G, and EL-B, and the electron transport region ETR of the first to third light emitting elements ED-R, ED-G, and ED-B may be in the pixel opening OH, and may be separate from the hole transport region HTR, the emission layers EL-R, EL-G, and EL-B, and the electron transport region ETR of the neighboring light emitting regions. In some embodiments, the hole transport region HTR, the emission layers EL-R, EL-G, and EL-B, and the electron transport region ETR may be patterned and provided in each pixel opening OH.

In the display device DD of an embodiment, the hole transport region HTR and an emission layer EL-R, EL-G, and EL-B, and the electron transport region ETR of each of the first to third light emitting elements ED-R, ED-G, and ED-B may be provided and formed through inkjet printing according to a method for manufacturing a display device of an embodiment, which will be further described below. However, embodiments of the present disclosure are not limited thereto. The hole transport region HTR, the emission layers EL-R, EL-G, and EL-B, and the electron transport region ETR may be provided and formed through a method other than inkjet printing, and also in some embodiments, at least a portion of the hole transport region HTR or the electron transport region ETR may extend to an upper portion of the pixel defining layer PDL, or at least a portion thereof may be connected.

In the display device DD of an embodiment, the second electrode CE and the capping layer CPL may each be provided as a common layer throughout the first to third light emitting elements ED-R, ED-G, and ED-B. However, embodiments of the present disclosure are not limited thereto, and at least one of the second electrode CE or the capping layer CPL may be provided to be separated in the neighboring light emitting regions PXA-R, PXA-G, and PXA-B.

In the display device DD of an embodiment, at least one of the first to third light emitting elements ED-R, ED-G, and ED-B may be an inorganic light emitting element including an inorganic luminous body in an emission layer, and the other light emitting elements may be organic light emitting elements including an organic luminous body in an emission layer. In an embodiment, one light emitting element selected from the first to third light emitting elements ED-R, ED-G, and ED-B may be an inorganic light emitting element, and the other two light emitting elements may be organic light emitting elements. In an embodiment, one light emitting element selected from the first to third light emitting elements ED-R, ED-G, and ED-B may be an organic light emitting element, and the other two light emitting elements may be inorganic light emitting elements.

In the display device DD of an embodiment shown in FIG. 3, the first light emitting element ED-R and the second light emitting element ED-G may be inorganic light emitting elements, and the third light emitting element ED-B may be an organic light emitting element. In some embodiments, in the display device DD of an embodiment, the first light emitting element ED-R and the second light emitting element ED-G may be organic light emitting elements, and the third light emitting element ED-B may be an inorganic light emitting element.

The third light emitting element ED-B may be different from the first light emitting element ED-R and the second light emitting element ED-G in that the third light emitting element ED-B includes a protection layer PIL. The protection layer PIL may be between the third emission layer EL-B and the electron transport region ETR.

The protection layer PIL may include a polar polymer. The protection layer PIL may be formed from a polar polymer material. In an embodiment, the protection layer PIL may include poly(ethylene glycol), poly(4-vinylpyridine), polyvinylpyrrolidone, and/or polyethyleneimine.

The polar polymer included in the protection layer PIL of an embodiment may be soluble in a polar organic solvent. For example, the polar organic solvent may be dimethyl sulfoxide, ethylene glycol, and/or an ether-based solvent.

The protection layer PIL in an embodiment may be formed using an inkjet printing method. The polar polymer may be dissolved in the polar organic solvent to prepare protection layer ink for forming the protection layer PIL. The polar polymer is easily dissolved in the polar organic solvent and provided in the form of ink, and the protection layer ink including the polar organic solvent may be easily ejected from a nozzle, and the like upon inkjet printing, thereby providing excellent workability.

The protection layer PIL may improve interface properties between adjacent organic and inorganic layers in a light emitting element, and may thus increase the luminous efficiency of the light emitting element. The protection layer PIL may be between the emission layer of the organic light emitting element including an organic luminous body and the inorganic electron transport layer including an inorganic electron transport material, or between the emission layer of the inorganic light emitting element including an inorganic luminous body and the organic electron transport layer including an organic electron transport material. The protection layer PIL may be between the emission layer of the organic light emitting element and the inorganic electron transport layer, or between the emission layer of the inorganic light emitting element and the organic electron transport layer, and may thus reduce a quenching phenomenon of the emission layer according to differences in material properties between the emission layer and the electron transport layer. In some embodiments, the protection layer PIL may prevent or reduce exciton quenching in the emission layer, which is caused by interfering with each layer according to the difference between organic and inorganic materials, allowing a light emitting element to exhibit excellent luminous efficiency.

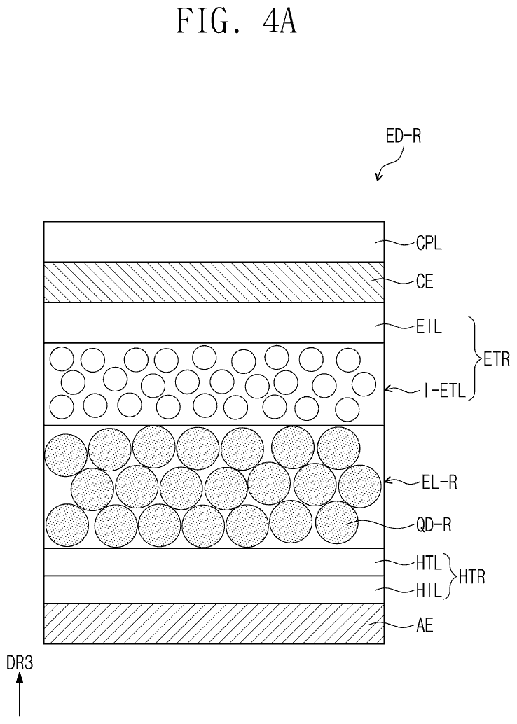

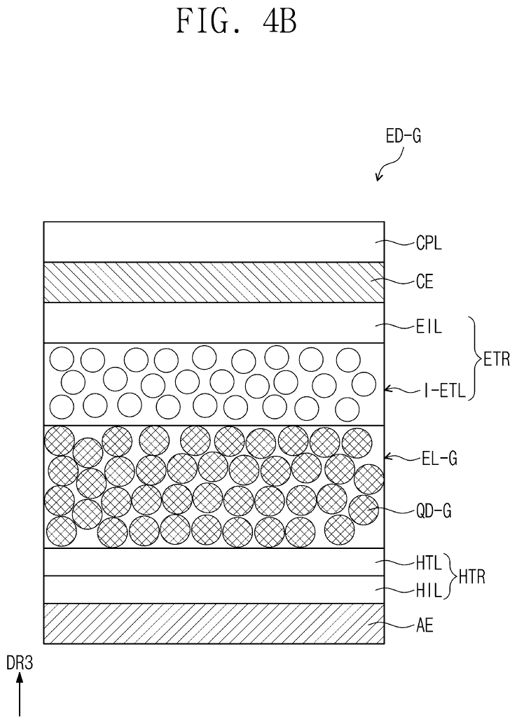

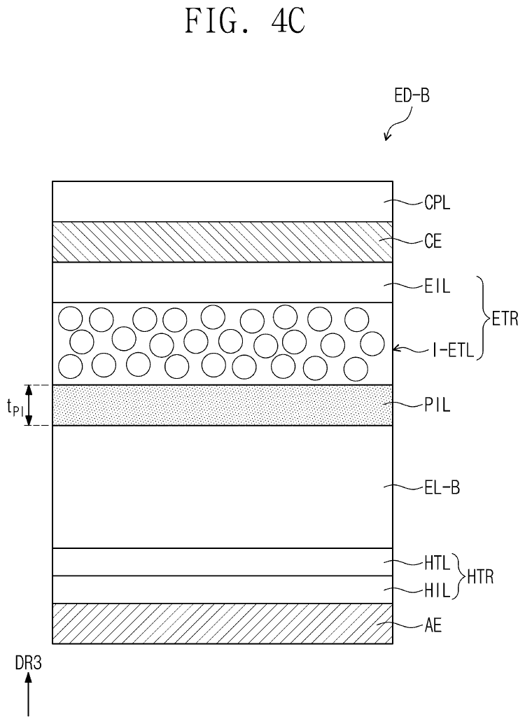

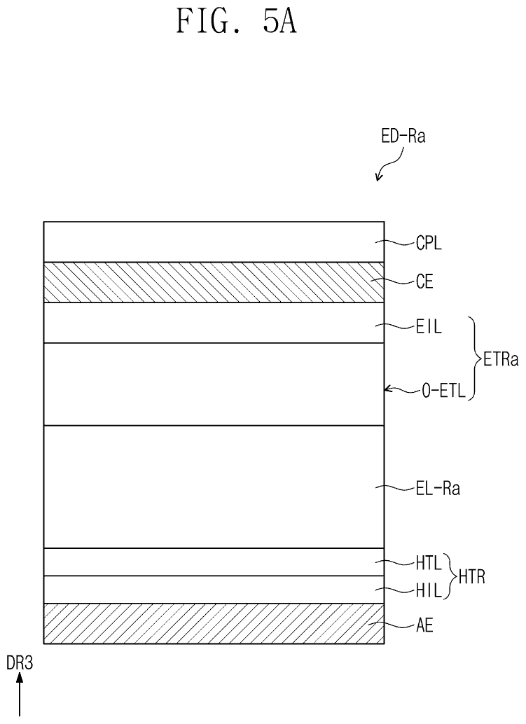

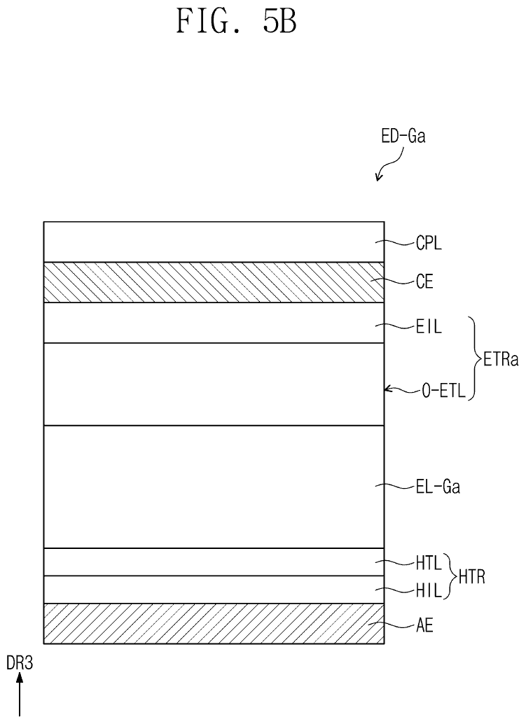

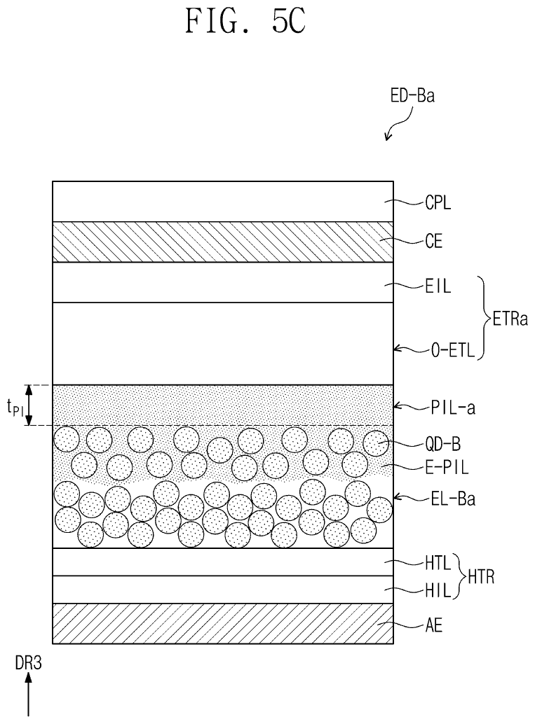

FIGS. 4A-5C are each cross-sectional views of light emitting elements included in a display device according to an embodiment. FIGS. 4A-5A are each cross-sectional views of the first light emitting element ED-R according to an embodiment, FIGS. 4B-5B are each cross-sectional views of the second light emitting element ED-G according to an embodiment, and FIGS. 4C-5C are each cross-sectional views of the third light emitting element ED-B according to an embodiment.

The first electrode AE may be a transmissive electrode, a transflective electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or an oxide thereof.

When the first electrode AE is the transmissive electrode, the first electrode AE may include a transparent metal oxide such as indium tin oxide (ITO), indium zinc oxide (IZO), zinc oxide (ZnO), and/or indium tin zinc oxide (ITZO). When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/AI (a stack structure of LiF and Al), Mo, Ti, W, a compound thereof, or a mixture thereof (e.g., a mixture of Ag and Mg). In some embodiments, the first electrode AE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode AE may have a three-layer structure of ITO/Ag/ITO, but is not limited thereto. In some embodiments, the first electrode AE may include the above-described metal materials, a combination of two or more metal materials selected from the above-described metal materials, and/or oxides of the above-described metal materials, and embodiments of the present disclosure are not limited thereto. The first electrode AE may have a thickness of about 700 Å to about 10000 Å. For example, the first electrode AE may have a thickness of 1000 Å to about 3000 Å.

The second electrode CE may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or an oxide thereof.

The second electrode CE may be a transmissive electrode, a transflective electrode, or a reflective electrode. When the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), and/or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (e.g., AgMg, AgYb, and/or MgYb). In some embodiments, the second electrode CE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode CE may include the above-described metal materials, a combination of two or more metal materials selected from the above-described metal materials, and/or oxides of the above-described metal materials.

In some embodiments, the second electrode CE may be connected with an auxiliary electrode. When the second electrode CE is connected with the auxiliary electrode, the resistance of the second electrode CE may decrease.

The first to third light emitting elements ED-R, ED-G, and ED-B may further include a capping layer CPL on the second electrode CE. The capping layer CPL may include a multilayer or a single layer.

In an embodiment, the capping layer CPL may be an organic layer and/or an inorganic layer. For example, when the capping layer CPL includes an inorganic material, the inorganic material may include an alkali metal compound such as LiF, an alkaline earth metal compound such as MgF₂, SION, SiNx, SiOy, and/or the like.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), and/or the like, and/or may include epoxy resins and/or acrylates such as methacrylates. However, embodiments of the present disclosure are not limited thereto, and the capping layer CPL may include at least one selected from compounds P1 to P5 below.

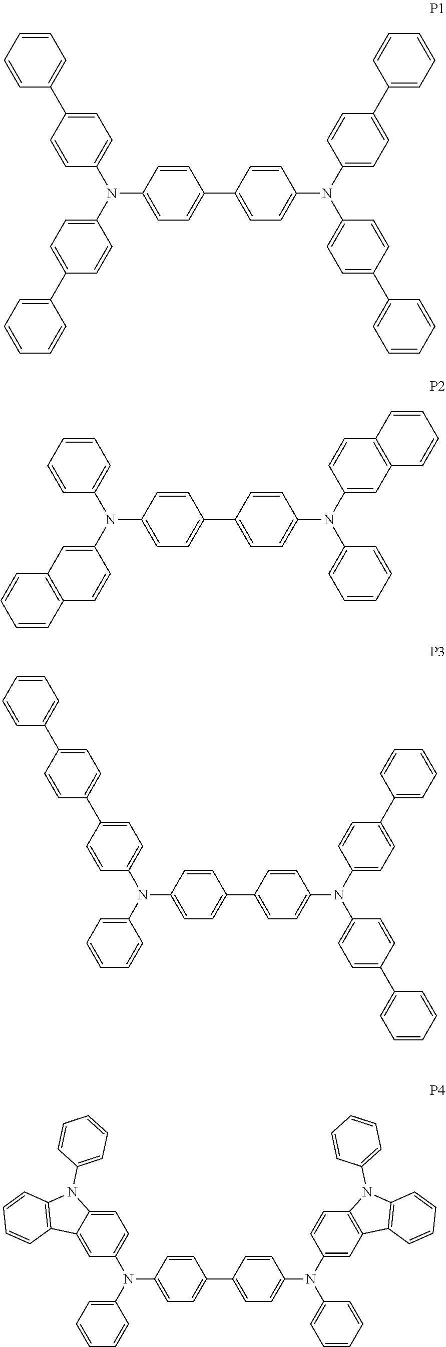 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

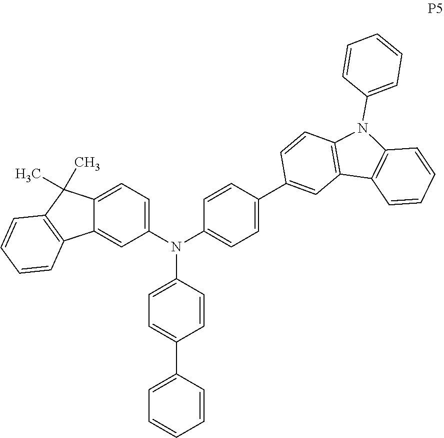 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or greater. For example, the capping layer CPL may have a refractive index of about 1.6 or greater in a wavelength range of about 550 nm to about 660 nm.

The hole transport region HTR may be on the first electrode AE. The hole transport region HTR may include a hole injection layer HIL, a hole transport layer HTL, etc. The hole transport region HTR may have a single layer formed of a single material, a single layer formed of a plurality of different materials, or a multilayer structure having a plurality of layers formed of a plurality of different materials.

In one embodiment, the hole transport region HTR may be formed through an inkjet printing method. However, embodiments of the present disclosure are not limited thereto, and the hole transport region HTR may be formed using various suitable methods such as a vacuum deposition method, a spin coating method, a cast method, a Langmuir-Blodgett (LB) method, and/or a laser induced thermal imaging (LITI) method.

The hole transport region HTR may include any suitable hole injection materials and/or suitable hole transport materials generally used in the art. In some embodiments, the hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-l-yl)-N,N′-diphenyl-benzidine (NPB), triphenylamine-including polyetherketone (TPAPEK), 4-isopropyl-4′-methyldiphenyliodonium tetrakis(pentafluorophenyl) borate, dipyrazino[2,3-f: 2′,3′-h] quinoxaline-2,3,6,7,10,11-hexacarbonitrile (HATCN), and/or the like.

In some embodiments, the hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl) benzene (mCP), 1,3-bis(1,8-dimethyl-9H-carbazol-9-yl)benzene (mDCP), and/or the like.

The hole transport region HTR may have a thickness of about 5 nm to about 1,500 nm, for example, about 10 nm to about 500 nm. When the thickness of the hole transport region HTR satisfies the above-described range, suitable or satisfactory hole transport properties may be obtained without a substantial increase in driving voltage.

The emission layer EL-R of the first light emitting element ED-R shown in FIG. 4A and the emission layer EL-G of the second light emitting element ED-G shown in FIG. 4B may each be an inorganic emission layer including an inorganic luminous body. The emission layer EL-R of the first light emitting element ED-R and the emission layer EL-G of the second light emitting element ED-G may each include quantum dots QD-R and QD-G. The emission layer EL-R of the first light emitting element ED-R may include red quantum dots QD-R that emit red light, and the emission layer EL-G of the second light emitting element ED-G may include green quantum dots QD-G that emit green light.

Herein, the quantum dots QD-R and QD-G that are inorganic luminous bodies may be InP-based quantum dots and/or Cd-based quantum dots. In some embodiments, the first light emitting element ED-R and the second light emitting element ED-G are inorganic luminous bodies and may include quantum dots including InP in the core and/or quantum dots including Cd in the core.

Embodiments of the present disclosure, however, are not limited thereto. The emission layer of an inorganic light emitting element may include various suitable types (or kinds) of quantum dots.

The quantum dot may be a crystal of a semiconductor compound. The quantum dot may emit light of various suitable emission wavelengths depending on the size of the crystal. The quantum dot may emit light of various suitable emission wavelengths by regulating an element ratio in the quantum dot compound.

The quantum dot may have a diameter of, for example, about 1 nm to about 10 nm. The quantum dot may be synthesized through a wet chemical process, a metal organic chemical vapor deposition process, a molecular beam epitaxy process, and/or a process similar thereto.

Among the quantum dot manufacturing processes, the wet chemical process is a method of mixing an organic solvent and a precursor material and then growing a quantum dot particle crystal. When the quantum dot particle crystal grows, the organic solvent naturally serves as a dispersant coordinated to a surface of the quantum dot crystal and may control the growth of the particle crystal. Therefore, the wet chemical process is easier than vapor deposition methods such as metal organic chemical vapor deposition (MOCVD) or molecular beam epitaxy (MBE), and may control the growth of quantum dot particles through a low-cost process.

A core of the quantum dot may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In some embodiments, the Group II-VI semiconductor compound may further include a Group I metal and/or a Group IV element. The Group I-II-VI compound may be selected from CuSnS and/or CuZnS, and the Group II-IV-VI compound may be selected from ZnSnS and the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, or a mixture thereof, and/or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and/or quaternary compound may be present in particles at a uniform concentration or a non-uniform concentration. In some embodiments, a formula representing quantum dots indicates the types (or kinds) of elements included in a compound, and element ratios in the compound may be different. For example, as described herein, AgInGaS₂ may indicate AgInₓGa₁₋ₓS₂ (x is a real number between 0 and 1).

In some embodiments, the binary compound, the ternary compound, and/or the quaternary compound may be present in particles having a uniform concentration distribution, or may be present in the same particles having a partially different concentration distribution. In some embodiments, a core/shell structure in which one quantum dot surrounds another quantum dot may be present. The core/shell structure may have a concentration gradient in which the concentration of an element present in the shell becomes lower along a direction towards the core.

In some embodiments, a quantum dot may have the core/shell structure including a core having nano-crystals, and a shell surrounding the core, which are described above. The shell of the quantum dot may serve as a protection layer to prevent or reduce the chemical deformation of the core so as to maintain semiconductor properties, and/or a charging layer to impart electrophoresis properties to the quantum dot. The shell may be a single layer or a plurality or layers. Examples of the shell of the quantum dot may be a metal and/or non-metal oxide, a semiconductor compound, or a combination thereof.

For example, the metal and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or a ternary compound such as MgAl₂O₄, CoFe₂O₄, NiFe₂O₄, and/or CoMn₂O₄, but embodiments of the present disclosure are not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have, in an emission wavelength spectrum, a full width of half maximum (FWHM) of about 45 nm or less, about 40 nm or less, or, for example, about 30 nm or less, and in the foregoing ranges, the color purity and/or the color reproducibility may be improved. In some embodiments, light emitted through the quantum dot is emitted in all (e.g., substantially all) directions, and thus a wide viewing angle may be improved.

In some embodiments, the form of a quantum dot is not particularly limited as long as it is a form generally used in the art, and for example, a quantum dot in the form of spherical, pyramidal, multi-arm, and/or cubic nanoparticles, nanotubes, nanowires, nanofibers, nanoplatelets, and/or the like may be used.

As the size of the quantum dot and/or the ratio of elements in the quantum dot compound is adjusted, the energy band gap may be accordingly controlled to obtain light of various suitable wavelengths from the quantum dot emission layer. Therefore, by using the quantum dots as described above (e.g., by using quantum dots of different sizes and/or having different element ratios in the quantum dot compound), a light emitting element that emits light of various suitable wavelengths may be obtained.

The emission layer EL-B of the third light emitting element ED-B shown in FIG. 4C may be an organic emission layer including an organic luminous body. The emission layer EL-B of the third light emitting element ED-B may include a host material and a dopant material. The emission layer EL-B of the third light emitting element ED-B may include a blue light emitting dopant. The dopant material included in the emission layer EL-B of the third light emitting element ED-B may be a fluorescent dopant or a thermally activated delayed fluorescent dopant. However, embodiments of the present disclosure are not limited thereto.

The emission layer EL-B may include anyone selected from H1-1 to H1-10 below as a host material. However, the host material included in the emission layer EL-B is not limited to the compounds below, and any suitable host materials used in an emission layer of an organic light emitting element may be used without limitation.

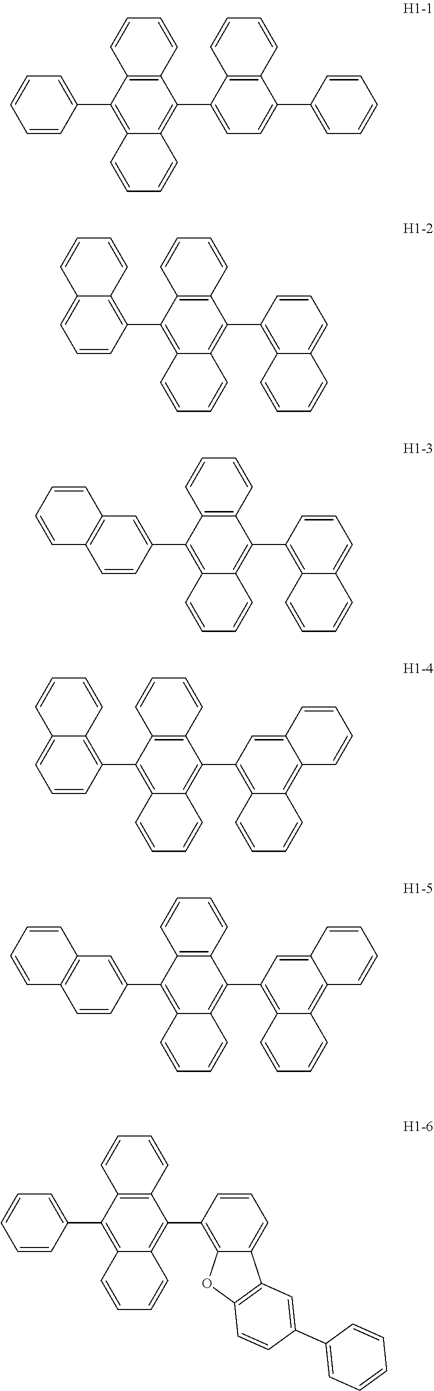

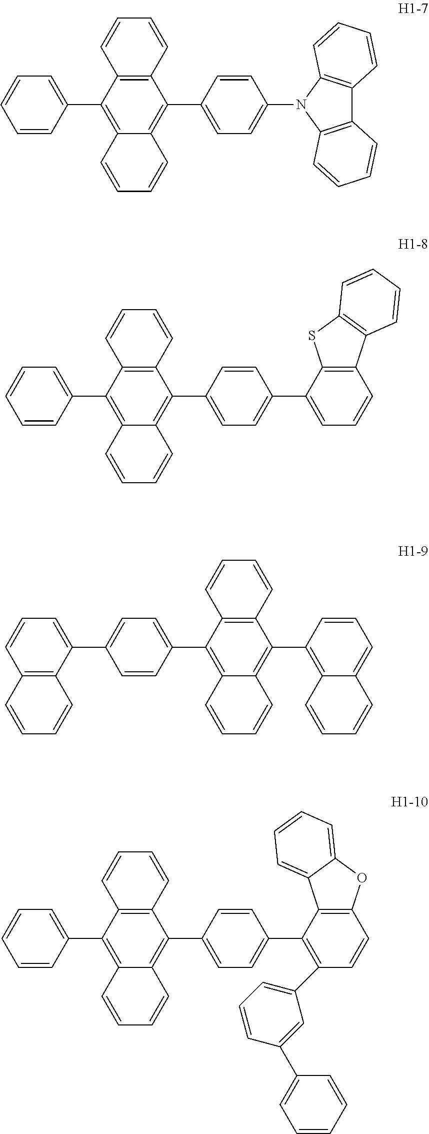

In an embodiment, any one of the hydrogen atoms of the compounds H1-1 to H1-10 above may each independently be substituted with a deuterium atom. For example, H1-1 above may be represented by H1-1D below.

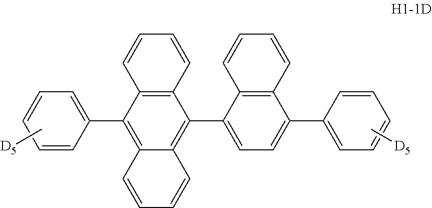

The emission layer EL-B may include at least one selected from the following FD1 to FD49 as a dopant material. However, the dopant material included in the emission layer EL-B is not limited to the compounds below, and any suitable dopant materials used in an emission layer of an organic light emitting element may be used without limitation.

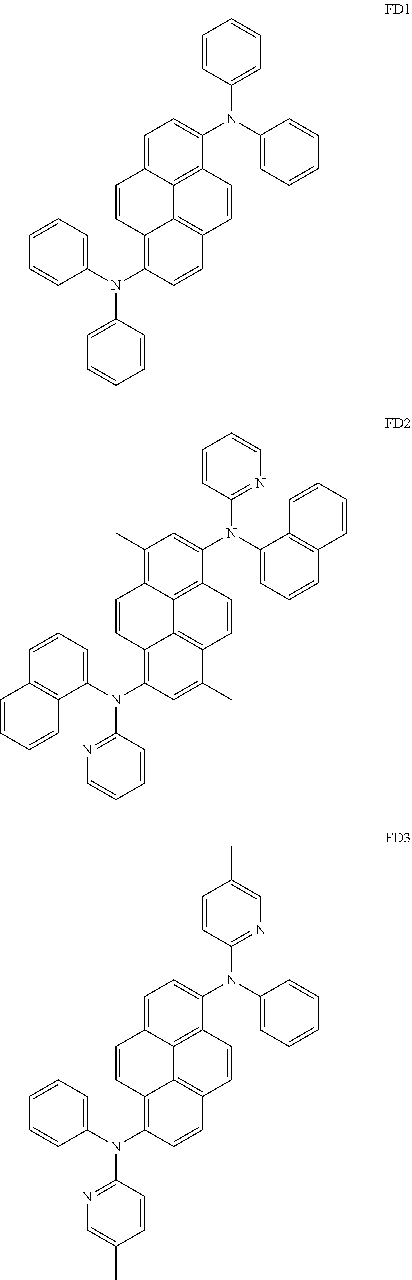 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

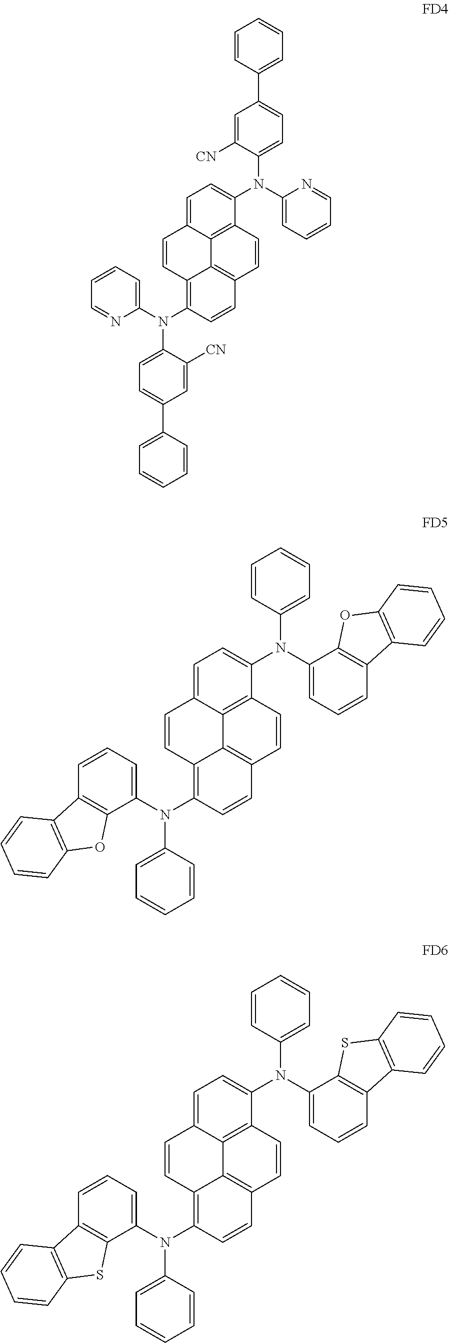

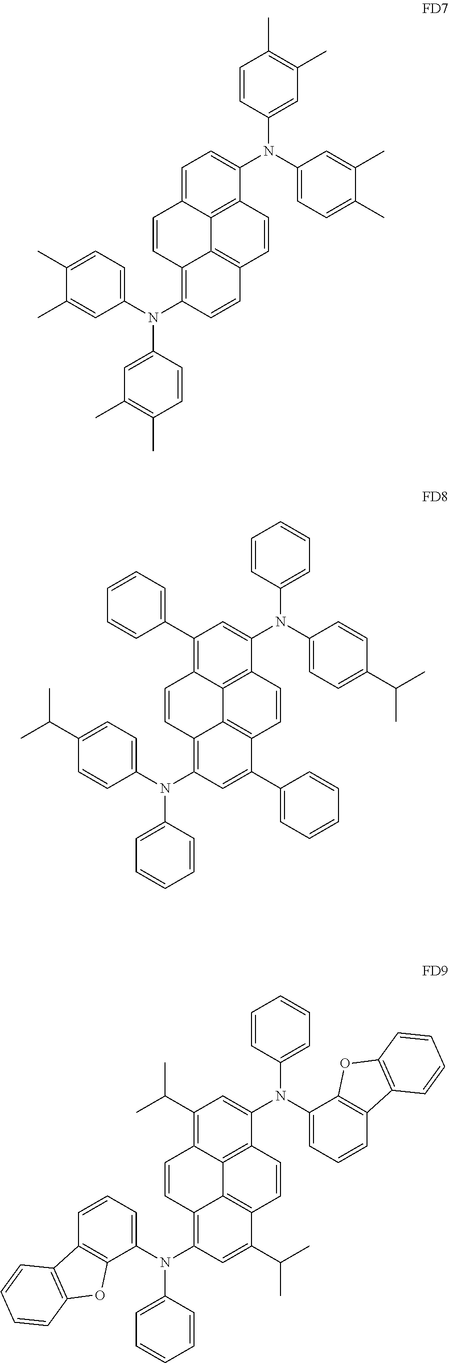

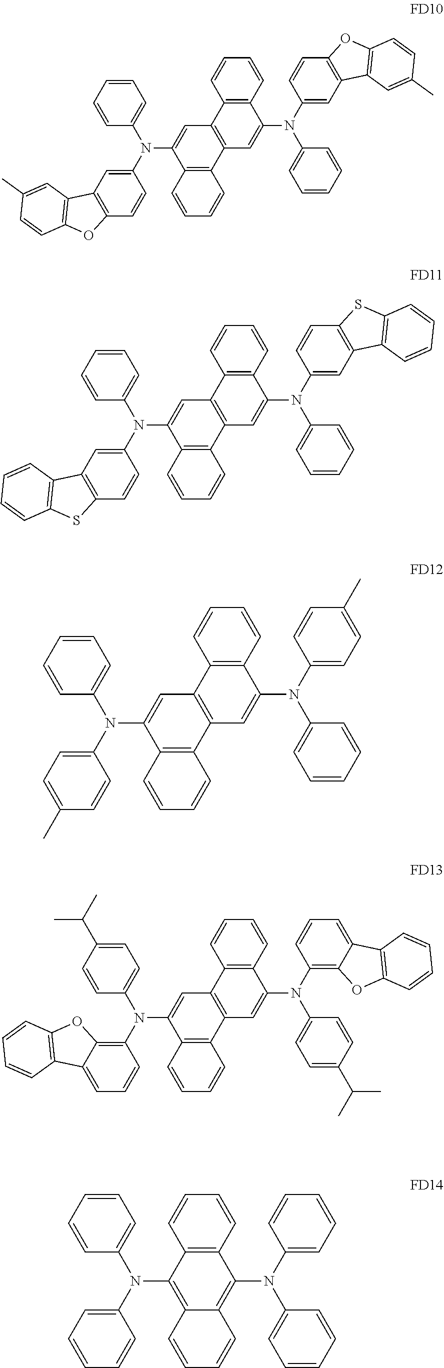

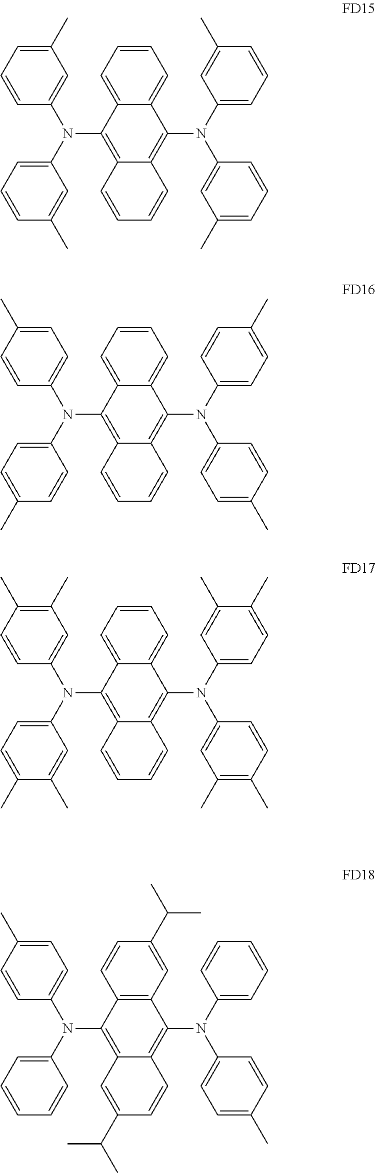 [SMILES: Cc1cccc(N(c2cccc(C)c2)c2c3ccccc3c(N(c3cccc(C)c3)c3cccc(C)c3)c3ccccc23)c1 ; Cc1ccc(N(c2ccc(C)cc2)c2c3ccccc3c(N(c3ccc(C)cc3)c3ccc(C)cc3)c3ccccc23)cc1 ; Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1]

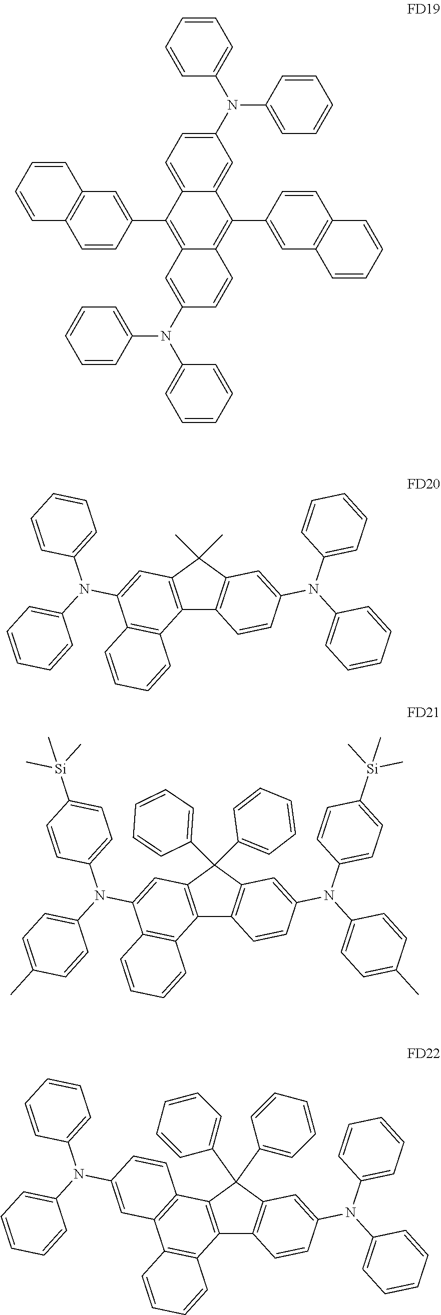

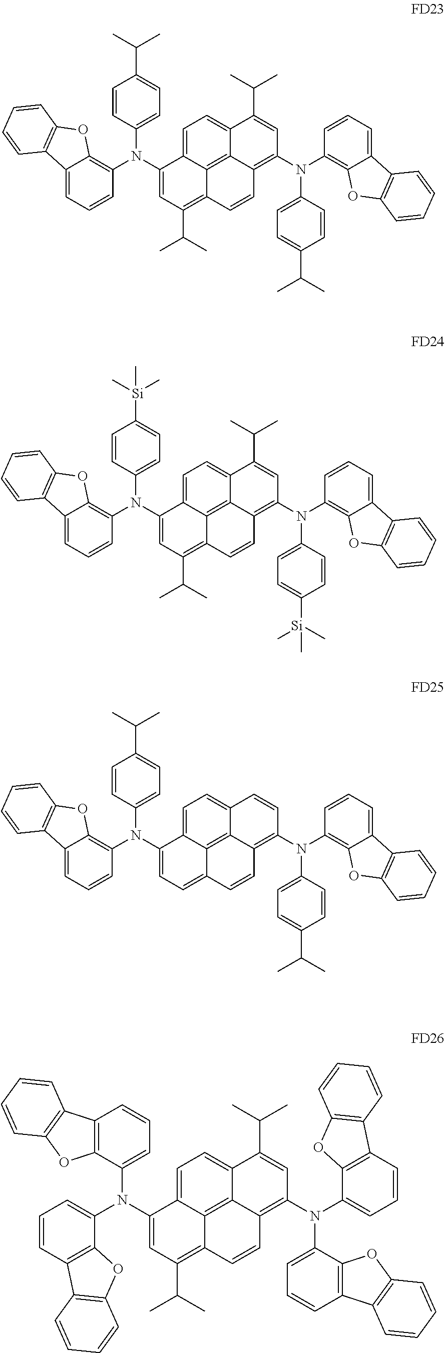 [SMILES: CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34]

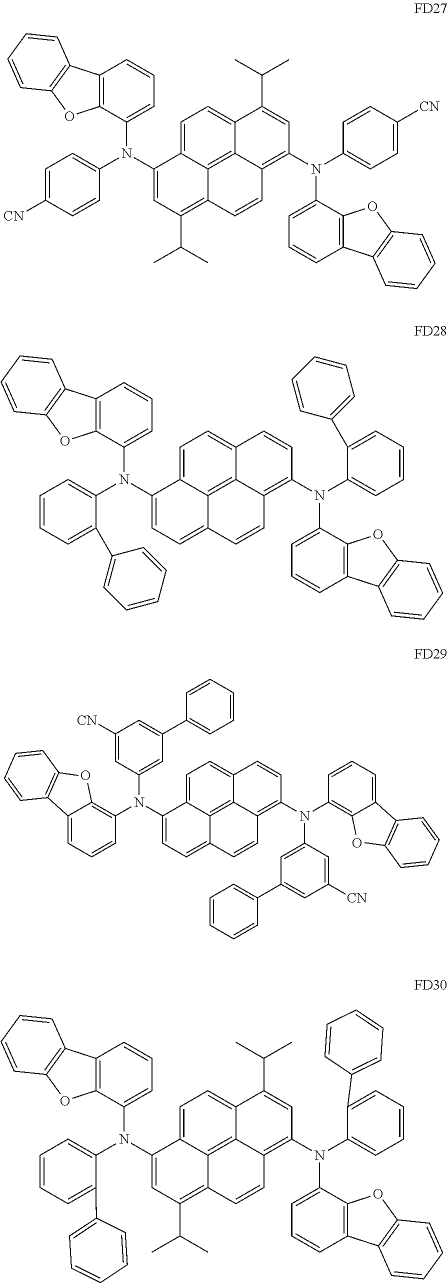

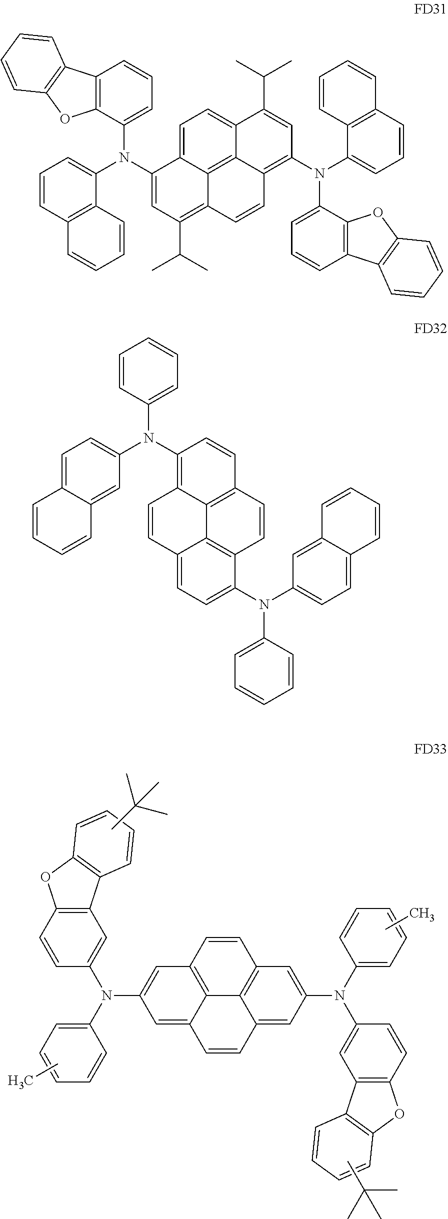

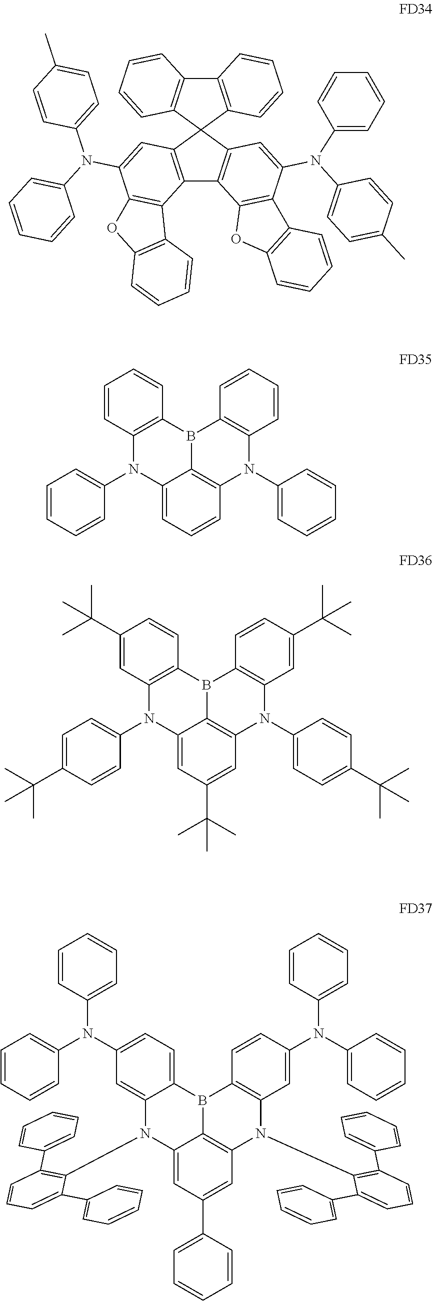

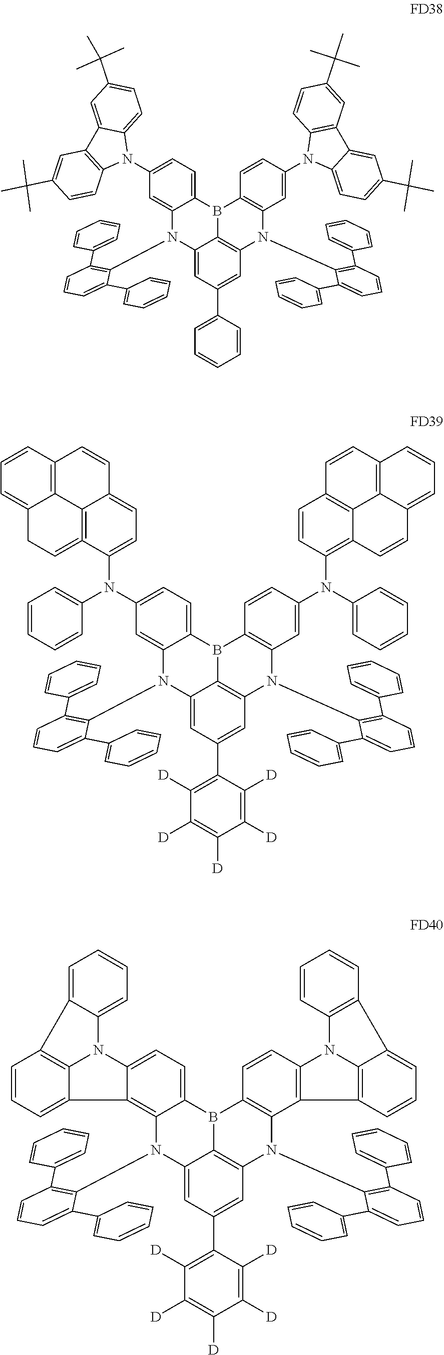

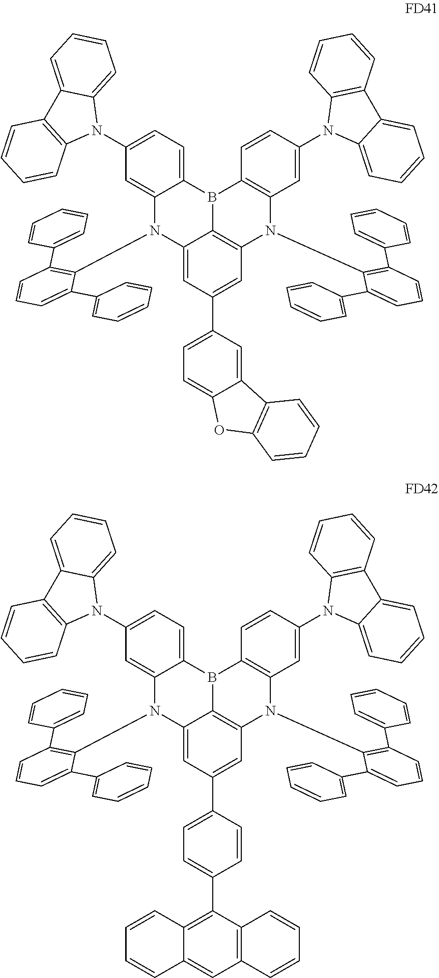 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5ccc6oc7ccccc7c6c5)cc2c43)cc1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5ccc(-c6c7ccccc7cc7ccccc67)cc5)cc2c43)cc1]

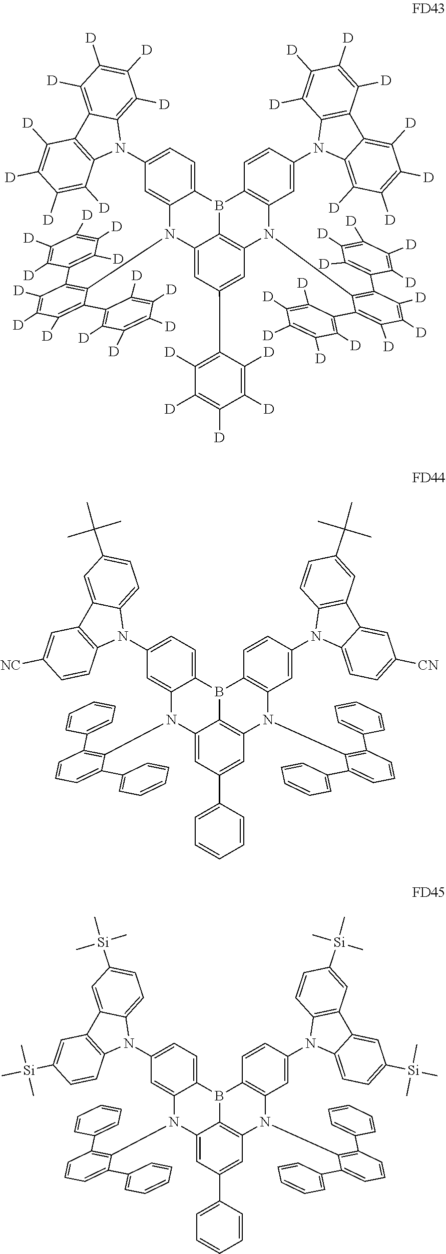

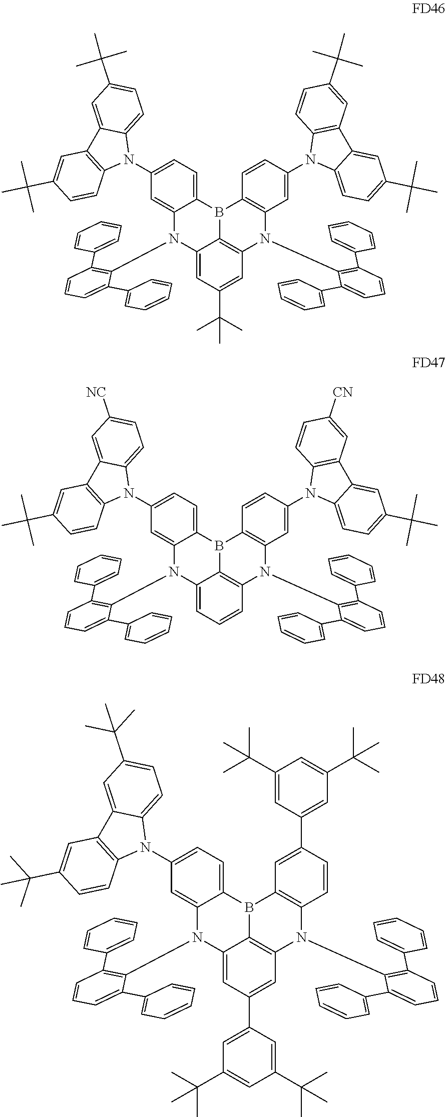

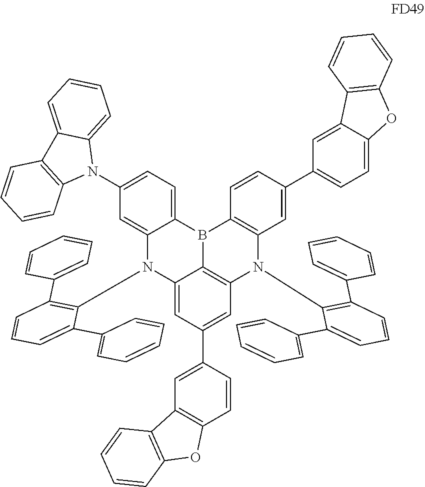 [SMILES: c1ccc(-c2cccc(-c3ccccc3)c2N2c3cc(-c4ccc5oc6ccccc6c5c4)ccc3B3c4ccc(-n5c6ccccc6c6ccccc65)cc4N(c4c(-c5ccccc5)cccc4-c4ccccc4)c4cc(-c5ccc6oc7ccccc7c6c5)cc2c43)cc1]

In the light emitting elements ED-R, ED-G, and ED-B shown in FIGS. 4A-4C, the electron transport region ETR may include an inorganic electron transport layer I-ETL including an inorganic electron transport material. In the light emitting elements ED-R, ED-G, and ED-B according to an embodiment, the electron transport region ETR may include an inorganic electron transport layer I-ETL and an electron injection layer EIL. In some embodiments, the electron injection layer EIL may not be provided.

The electron transport region ETR may have a single layer formed of a single material, a single layer formed of a plurality of different materials, or a multilayer structure having a plurality of layers formed of a plurality of different materials. For example, the electron transport region ETR may have a single-layer structure of an inorganic electron transport layer I-ETL including an inorganic electron transport material. The electron transport region ETR may have a thickness of, for example, about 20 nm to about 150 nm.

The electron transport region ETR may be formed through inkjet printing. However, embodiments of the present disclosure are not limited thereto, and the electron transport region ETR may be formed using various suitable methods such as a vacuum deposition method, a spin coating method, a cast method, a Langmuir-Blodgett (LB) method, and/or a laser induced thermal imaging (LITI) method.

The inorganic electron transport layer I-ETL may include metal inorganic nanoparticles as an inorganic electron transport material. The inorganic electron transport material may include TiO₂, ZnO, ZnMgO, ZnAlO, SnO₂, Li₂O, and/or BaO. For example, in some embodiments, the inorganic electron transport layer I-ETL may include at least one of TiO₂, ZnO, ZnMgO, ZnAlO, SnO₂, Li₂O, and/or BaO. Metal inorganic particles may be inked through a Sol-Gel technique and provided through an inkjet printing method to form the inorganic electron transport layer I-ETL.

The inorganic electron transport layer I-ETL may be formed using the same material on the emission layers EL-R, EL-G, and EL-B of each of the first to third light emitting elements ED-R, ED-G, and ED-B, and using the same method of manufacturing.

When the first to third light emitting elements ED-R, ED-G, and ED-B each have the structures of FIGS. 4A-4C, the third light emitting element ED-B may include a protection layer PIL. In some embodiments, when the inorganic electron transport layer I-ETL including an inorganic electron transport material is included, the protection layer PIL may be on the emission layer EL-B of the third light emitting element ED-B including an organic luminous body.

In the third light emitting element ED-B, the protection layer PIL is directly between the emission layer EL-B including an organic luminous body and the inorganic electron transport layer I-ETL, and may thus prevent or reduce direct contact between the emission layer EL-B and the inorganic electron transport material.

The protection layer PIL is between the emission layer EL-B and the inorganic electron transport layer I-ETL, and may thus prevent quenching from taking place in the emission layer due to the inorganic electron transport material (or reduce a likelihood or amount of such quenching). In some embodiments, even when the third light emitting element ED-B including an organic emission layer is provided with the same inorganic electron transport material as the first light emitting element ED-R and the second light emitting element ED-G including an inorganic emission layer, excellent luminous efficiency of the third light emitting element ED-B may be maintained without reduction in luminous efficiency.

In the third light emitting element ED-B, the protection layer PIL may have a thickness (t_{PI}) of about 50 Å to about 200 Å. When the thickness (t_{PI}) of the protection layer PIL is less than about 50 Å, the protection layer PIL fails to sufficiently protect the emission layer EL-B, thereby providing no improvements in luminous efficiency, and when the thickness (t_{PI}) of the protection layer PIL is greater than about 200 Å, the protection layer PIL serves as an insulating layer (e.g., an electrically insulating layer), making it difficult for electrons to move, resulting in a decrease in luminous efficiency.

When the display device DD of an embodiment shown in FIG. 3 has the structure of the first light emitting element ED-R, the second light emitting element ED-G, and the third light emitting element ED-B described with reference to FIGS. 4A-4C, the same material of the electron transport region ETR may be used in the light emitting elements regardless of whether an inorganic luminous body and an organic luminous body are provided in the emission layer of the light emitting element, and excellent luminous efficiency may be achieved over all the light emitting elements.

FIGS. 5A-5C each show an embodiment of a light emitting element corresponding to the first to third light emitting elements included in the display layer EDL of the display device DD of the embodiment shown in FIG. 3. The contents described with reference to FIGS. 4A-4C may also apply to the components of the first electrode AE, the hole transport region HTR, the second electrode CE, and the capping layer CPL.

An emission layer EL-Ra of a first light emitting element ED-Ra shown in FIG. 5A and an emission layer EL-Ga of a second light emitting element ED-Ga shown in FIG. 5B may each be an organic emission layer including an organic luminous body. The emission layer EL-Ra of the first light emitting element ED-Ra and the emission layer EL-Ga of the second light emitting element ED-Ga may each include a host material and a dopant material. The emission layer EL-Ra of the first light emitting element ED-Ra may include a red light emitting dopant, and the emission layer EL-Ga of the second light emitting element ED-Ga may include a green light emitting dopant. The dopant material included in the emission layers EL-Ra and EL-Ga of the first light emitting element ED-Ra and the second light emitting element ED-Ga may be a fluorescent dopant or a phosphorescent dopant. However, embodiments of the present disclosure are not limited thereto.

As a host material, at least one of bis[2-(diphenylphosphino)phenyl]ether oxide (DPEPO), 4,4′-bis(carbazol-9-yl)biphenyl (CBP), 1,3-bis(N-carbazolyl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi) may be included. However, the type (or kind) of host material is not limited thereto, and for example, tris(8-hydroxyquinolino)aluminum (Alq₃), poly(N-vinylcarbazole) (PVK), 9,10-di(naphthalene-2-yl)anthracene (ADN), 3-tert-butyl-9,10-di(naphth-2-yl)anthracene (TBADN), distyrylarylene (DSA), 4,4-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

In an embodiment, as the host material, any one selected from among the following compounds E1 to E19 may be included. However, embodiments of the present disclosure are not limited thereto.

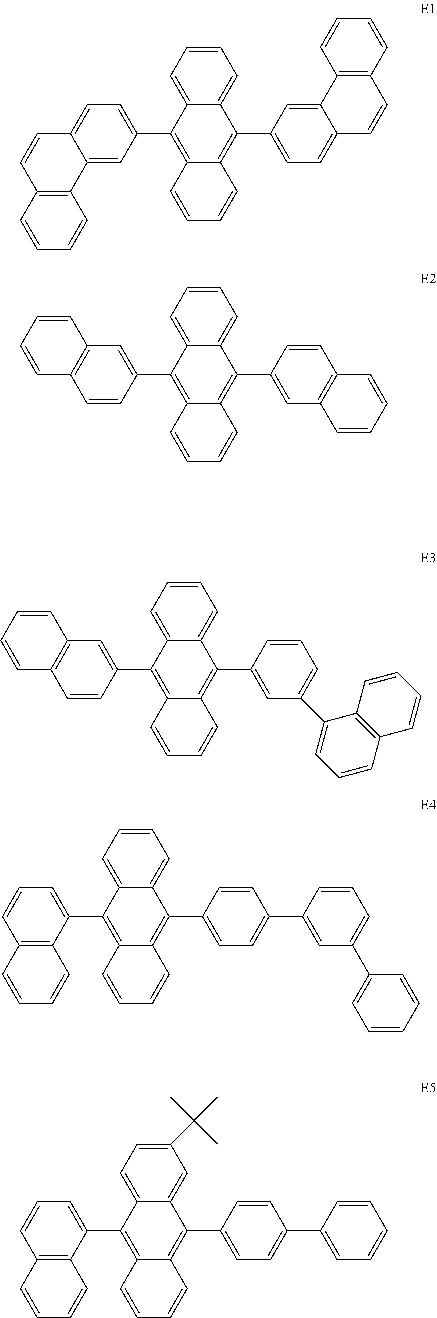

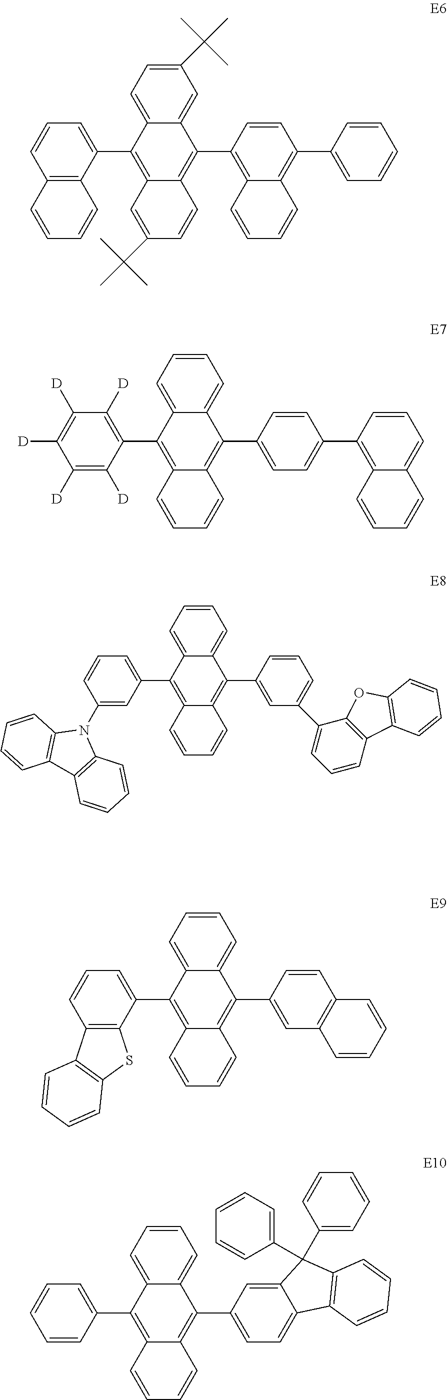

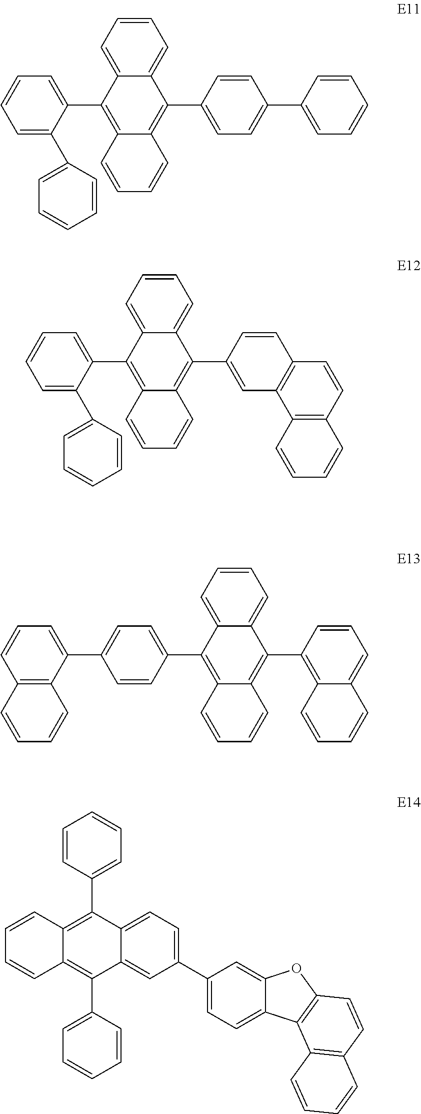

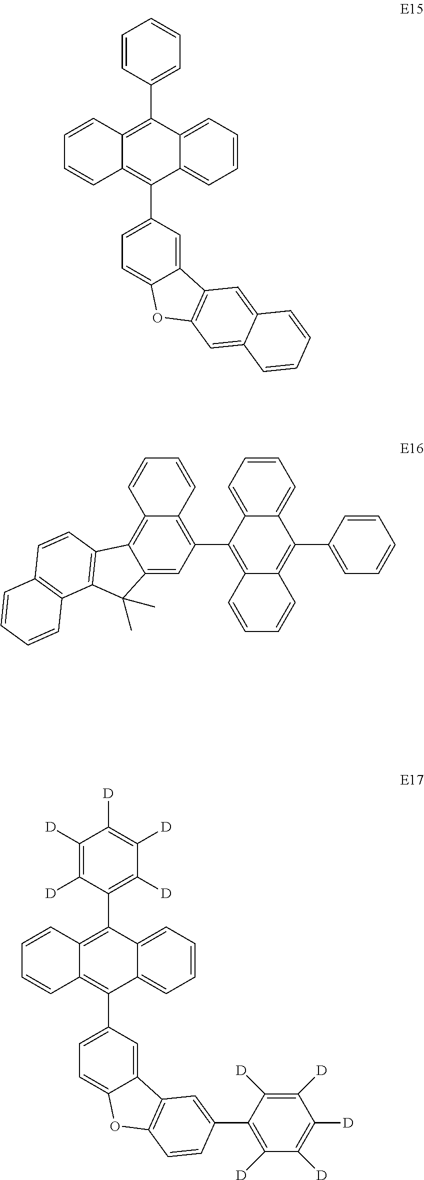

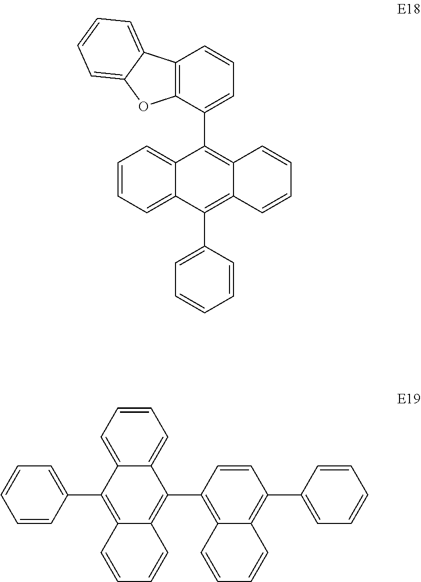

In an embodiment, as a dopant material, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and/or derivatives thereof (e.g., 2,5,8,11-tetra-t-butylperylene (TBP)), pyrene and/or derivatives thereof (e.g., 1,1-dipyrene, 1,4-dipyrenylbenzene, 1,4-bis(N,N-diphenylamino) pyrene), and/or the like may be further included.

In some embodiments, as the dopant material, any suitable phosphorescent dopant material generally used in the art may be included. In some embodiments, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), and/or thulium (Tm) may be used. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), platinum octaethyl porphyrin (PtOEP), and/or the like may be used as a phosphorescent dopant. However, embodiments of the present disclosure are not limited thereto.

An emission layer EL-Ba of a third light emitting element ED-Ba shown in FIG. 5C may be an inorganic emission layer including an inorganic luminous body. The emission layer EL-Ba of the third light emitting element ED-Ba may include quantum dots QD-B. The emission layer EL-Ba of the third light emitting element ED-Ba may include blue quantum dots QD-B that emit blue light. The blue quantum dots QD-B may be InP-based quantum dots and/or Cd-based quantum dots. In some embodiments, the blue quantum dots QD-B are semiconductor compound crystals, and the description of quantum dots described above may also apply to the blue quantum dots QD-B.

In the light emitting elements ED-Ra, ED-Ga, and ED-Ba shown in FIGS. 5A-5C, an electron transport region ETRa may include an organic electron transport layer O-ETL including an organic electron transport material. In the light emitting elements ED-Ra, ED-Ga, and ED-Ba according to an embodiment, the electron transport region ETRa may include an organic electron transport layer O-ETL and an electron injection layer EIL. In some embodiments, the electron injection layer EIL may not be provided.

The electron transport region ETRa may have a single layer formed of a single material, a single layer formed of a plurality of different materials, or a multilayer structure having a plurality of layers formed of a plurality of different materials. For example, the electron transport region ETRa may have a single-layer structure of an organic electron transport layer O-ETL including an organic electron transport material. The electron transport region ETRa have a thickness of, for example, about 20 nm to about 150 nm.

The electron transport region ETRa may be formed through inkjet printing. However, embodiments of the present disclosure are not limited thereto, and the electron transport region ETRa may be formed using various suitable methods such as a vacuum deposition method, a spin coating method, a cast method, a Langmuir-Blodgett (LB) method, and/or a laser induced thermal imaging (LITI) method.

In some embodiments, the organic electron transport layer O-ETL may include at least one selected from the following organic electron transport materials.

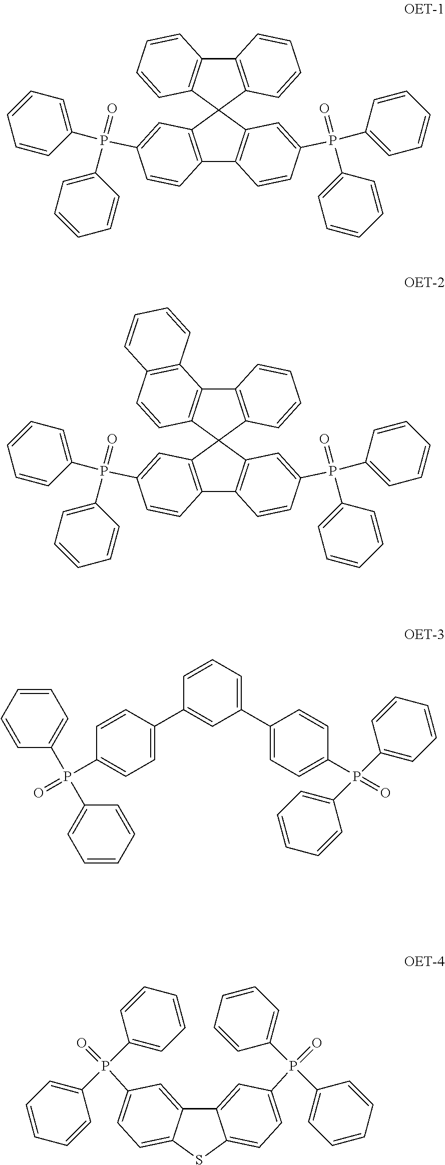 [SMILES: O=P(c1ccccc1)(c1ccccc1)c1ccc2c(c1)C1(c3ccccc3-c3ccccc31)c1cc(P(=O)(c3ccccc3)c3ccccc3)ccc1-2 ; O=P(c1ccccc1)(c1ccccc1)c1ccc2c(c1)C1(c3cc(P(=O)(c4ccccc4)c4ccccc4)ccc3-2)c2ccccc2-c2c1ccc1ccccc21 ; O=P(c1ccccc1)(c1ccccc1)c1ccc(-c2cccc(-c3ccc(P(=O)(c4ccccc4)c4ccccc4)cc3)c2)cc1 ; O=P(c1ccccc1)(c1ccccc1)c1ccc2sc3ccc(P(=O)(c4ccccc4)c4ccccc4)cc3c2c1]

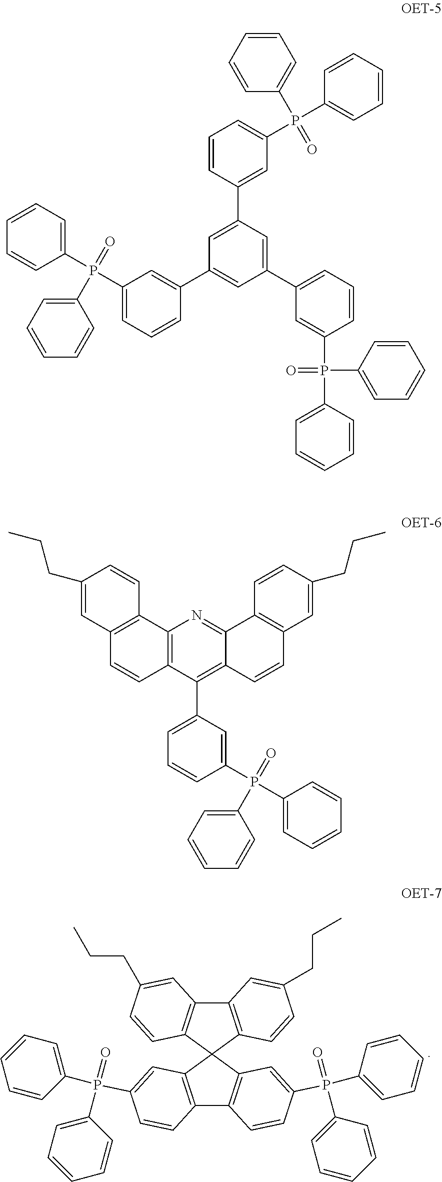 [SMILES: O=P(c1ccccc1)(c1ccccc1)c1cccc(-c2cc(-c3cccc(P(=O)(c4ccccc4)c4ccccc4)c3)cc(-c3cccc(P(=O)(c4ccccc4)c4ccccc4)c3)c2)c1 ; CCCc1ccc2c(ccc3c(-c4cccc(P(=O)(c5ccccc5)c5ccccc5)c4)c4ccc5cc(CCC)ccc5c4nc32)c1 ; CCCc1ccc2c(c1)-c1cc(CCC)ccc1C21c2cc(P(=O)(c3ccccc3)c3ccccc3)ccc2-c2ccc(P(=O)(c3ccccc3)c3ccccc3)cc21]

In some embodiments, the organic electron transport layer O-ETL may include any suitable organic electron transport material generally used in the art. In some embodiments, the organic electron transport layer O-ETL may include, for example, tris(8-hydroxyquinolinato)aluminum (Alq₃), 1,3,5-tri[(3-pyridyl)-phen-3-yl]benzene, 2,4,6-tris(biphenyl-3-yl)-1,3,5-triazine (T2T), 2,4,6-tris(3-(pyrimidin-5-yl)phenyl)-1,3,5-triazine (TPM-TAZ), 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The organic electron transport layer O-ETL may be formed using the same material on the emission layers EL-Ra, EL-Ga, and EL-Ba of each of the first to third light emitting elements ED-Ra, ED-Ga, and ED-Ba, and using the same method of manufacturing.

When the first to third light emitting elements ED-Ra, ED-Ga, and ED-Ba each have the structures of FIGS. 5A-5C, the third light emitting element ED-Ba may include a protection layer PIL-a. In some embodiments, when the organic electron transport layer O-ETL including an organic electron transport material is included, the protection layer PIL-a may be on the emission layer EL-Ba of the third light emitting element ED-Ba including an inorganic luminous body.

In the third light emitting element ED-Ba, the protection layer PIL-a is directly between the emission layer EL-Ba including the quantum dots QD-B and the organic electron transport layer O-ETL, and may thus prevent or reduce direct contact between the quantum dots QD-B of the emission layer EL-Ba and the organic electron transport material.

The protection layer PIL-a is between the emission layer EL-Ba and the organic electron transport layer O-ETL, and may thus prevent quenching from taking place in the emission layer due to the organic electron transport material (or reduce a likelihood or amount of such quenching). In some embodiments, even when the third light emitting element ED-Ba including an inorganic emission layer is provided with the same organic electron transport material as the first light emitting element ED-Ra and the second light emitting element ED-Ga including an organic emission layer, excellent luminous efficiency of the third light emitting element ED-Ba may be maintained without reduction in luminous efficiency.

When the protection layer PIL-a is provided on the emission layer EL-Ba including an inorganic luminous body, a portion of the protection layer PIL-a may be provided to permeate between the emission layers EL-Ba. A portion of a protection layer E-PIL may permeate between the quantum dots QD-B, which are inorganic luminous bodies, and may fill a space between the quantum dots QD-B. In FIG. 5A, the protection layer PIL-a is shown to enter into only an upper portion of the emission layer EL-Ba, but embodiments of the present disclosure are not limited thereto, and the protection layer PIL-a may enter into a lower portion of the emission layer EL-Ba or only a portion of the upper portion of the emission layer EL-Ba.

Th above may cause voids between a plurality of inorganic particles in the case of inorganic luminous bodies such as quantum dots QD-B, and when a protection layer ink is provided on the upper portion of the emission layer EL-Ba to form a protection layer, a portion of the protection layer ink may enter into the space between the quantum dots due to the flowability of the protection layer ink, and may remain in the form that the protection layer E-PIL enters.

In the third light emitting element ED-Ba, the protection layer PIL-a may have a thickness (t_{PI}) of about 50 Å to about 200 Å. The thickness (t_{PI}) of the protection layer PIL-a on the emission layer EL-Ba of the third light emitting element ED-Ba, which is an inorganic emission layer, may be defined as a gap between an uppermost surface of the emission layer, which is defined by the quantum dots QD-B constituting the emission layer EL-Ba, and the organic electron transport layer O-ETL.

When the thickness (t_{PI}) of the protection layer PIL-a is less than about 50 Å, the protection layer PIL-a fails to sufficiently protect the emission layer EL-Ba, thereby providing no improvements in luminous efficiency, and when the thickness (t_{PI}) of the protection layer PIL-a is greater than about 200 Å, the protection layer PIL-a serves as an insulating layer (e.g., an electrically insulating layer), making it difficult for electrons to move, resulting in a decrease in luminous efficiency.

The first to third light emitting elements ED-R, ED-G, and ED-B included in the display device DD of an embodiment shown in FIG. 3 may have a combination of the light emitting elements shown in FIGS. 4A-4C or a combination of the light emitting elements shown in FIGS. 5A-5C.

In the display device DD of some embodiments, two light emitting elements selected from the first to third light emitting elements are inorganic light emitting elements and the other one is an organic light emitting element, an inorganic electron transport layer is included in all the light emitting elements, and a protection layer is included in an organic light emitting element among the light emitting elements, and accordingly, interface properties between the emission layer of the organic light emitting element and the inorganic electron transport layer may be improved, resulting in excellent luminous efficiency. In the display device DD of some embodiments, two light emitting elements selected from the first to third light emitting elements are organic light emitting elements and the other one is an inorganic light emitting element, an organic electron transport layer is included in all the light emitting elements, and a protection layer is included in an inorganic light emitting element among the light emitting elements, and accordingly, interface properties between the emission layer of the inorganic light emitting element and the organic electron transport layer may be improved, resulting in excellent luminous efficiency.

In some embodiments, the third light emitting element ED-B disposed corresponding to the third light emitting region PXA-B that emits blue light includes an organic luminous body in the emission layer EL-B, and includes a blue organic luminous body having greater service life than blue quantum dots in the emission layer EL-B, and accordingly, the third light emitting element ED-B may also exhibit excellent luminous efficiency and service life. In addition, the electron transport region ETR of the first to third light emitting elements ED-R, ED-G, and ED-B includes an inorganic electron transport layer, and accordingly, the light emitting elements may have increased luminous efficiency due to an increase in electron mobility, resulting from the excellent electron mobility of inorganic electron transport materials. In addition, the third light emitting element ED-B also includes a protection layer between the organic emission layer and the inorganic electron transport layer, and may thus maintain excellent luminous efficiency without quenching in the emission layer.

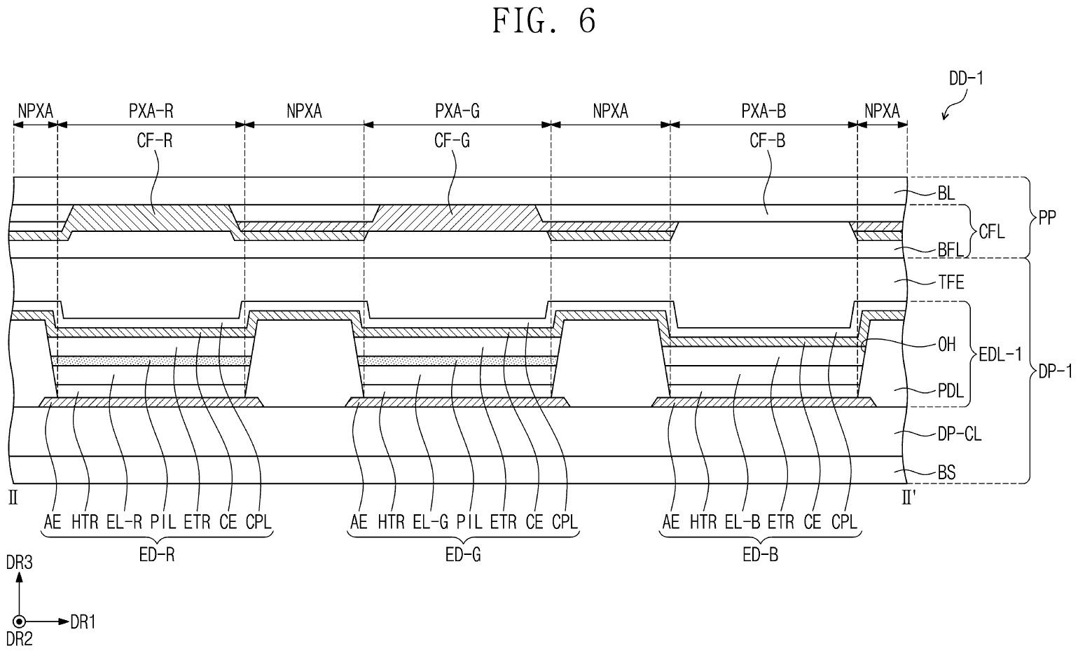

FIG. 6 is a cross-sectional view of a display device according to an embodiment. FIG. 6 is a cross-sectional view of a portion corresponding to line II-II′ of FIG. 1. A display device DD-1 of an embodiment shown in FIG. 6 differs from the display device DD of an embodiment shown in FIG. 3 only in the components of a display layer EDL-1. Among the components in FIG. 6, those that overlap the components of the display device DD in FIG. 3 will not be described again, and the differences will be mainly described.

Referring to FIG. 6, in the display layer EDL-1 included in the display device DD-1 of an embodiment, the first light emitting element ED-R and the second light emitting element ED-G may include a protection layer PIL. The third light emitting element ED-B may not include a protection layer PIL.

In the display device DD-1 of an embodiment, the first light emitting element ED-R and the second light emitting element ED-G are organic light emitting elements and the third light emitting element ED-B is an inorganic light emitting element, and the electron transport region ETR may include an inorganic electron transport material. In some embodiments, the protection layer PIL may be between the electron transport region ETR including an inorganic electron transport material and the emission layers EL-R and EL-G of the organic light emitting element. In some embodiments, the first light emitting element ED-R and the second light emitting element ED-G may have a stack structure of light emitting elements, which is similar to the stack structure in FIG. 4C. However, compared to FIG. 4C, there may be a difference in the dopant material of the emission layer, and accordingly, there is a difference in the light emission wavelength.

In some embodiments, in the display device DD-1, the first light emitting element ED-R and the second light emitting element ED-G are inorganic light emitting elements and the third light emitting element ED-B is an organic light emitting element, and the electron transport region ETR may include an organic electron transport material. In some embodiments, the protection layer PIL may be between the electron transport region ETR including an organic electron transport material and the emission layers EL-R and EL-G of the inorganic light emitting element. In some embodiments, the first light emitting element ED-R and the second light emitting element ED-G may have a stack structure of light emitting elements, which is similar to the stack structure in FIG. 5C. However, compared to FIG. 5C, there is a difference in the emission wavelength of the inorganic luminous body included in the emission layer.

In the display device DD of an embodiment, two light emitting elements selected from the first to third light emitting elements are inorganic light emitting elements and the other one is an organic light emitting element, an organic electron transport layer is included in all the light emitting elements, and a protection layer is included in each inorganic light emitting element among the light emitting elements, and accordingly, interface properties between the emission layer of the inorganic light emitting element and the organic electron transport layer may be improved, resulting in excellent luminous efficiency. In the display device DD-1 of some embodiments, two light emitting elements selected from the first to third light emitting elements are organic light emitting elements and the other one is an inorganic light emitting element, an inorganic electron transport layer is included in all the light emitting elements, and a protection layer is included in each organic light emitting element among the light emitting elements, and accordingly, interface properties between the emission layer of the organic light emitting element and the inorganic electron transport layer may be improved, resulting in excellent luminous efficiency.

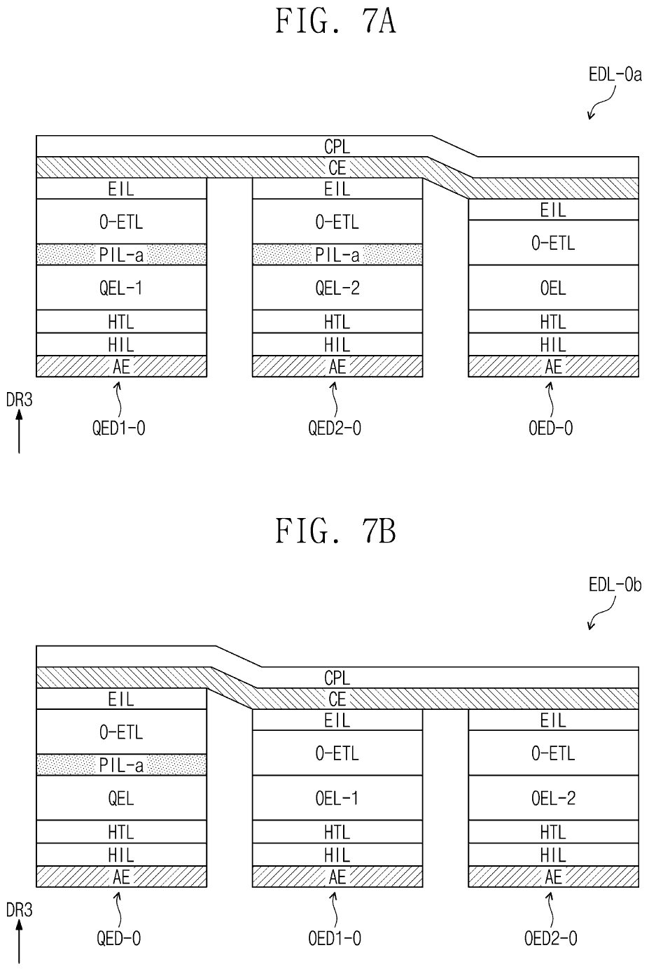

FIGS. 7A-7B are cross-sectional views illustrating Examples of display layers included in a display device of an embodiment. The contents described with reference to FIGS. 4A-5C may also apply to the components of light emitting elements included in the display layers shown in FIGS. 7A-7B.

FIGS. 7A-7B correspond to a case where display layers EDL-Oa and EDL-Ob each include an organic electron transport layer O-ETL.

The display layer EDL-Oa according to an embodiment shown in FIG. 7A may include two inorganic light emitting elements QED1-O and QED2-O and one organic light emitting element OED-O. In some embodiments, the organic light emitting element OED-O may be any one among a blue light emitting element, a green light emitting element, or a red light emitting element, and the other light emitting elements may each be inorganic light emitting elements QED1-O and QED2-O. In the display layer EDL-Oa according to an embodiment, the protection layer PIL-a may be between inorganic emission layers QEL-1 and QEL-2 of the inorganic light emitting elements QED1-O and QED2-O and the organic electron transport layer O-ETL. In FIG. 7A, the first inorganic light emitting element QED1-O, the second inorganic light emitting element QED2-O, and the organic light emitting element OED-O are shown to be arranged in that order, but the arrangement order is not limited to thereto.

The display layer EDL-Ob according to an embodiment shown in FIG. 7B may include two organic light emitting elements OED1-O and OED2-O and one inorganic light emitting element QED-O. In some embodiments, the inorganic light emitting element QED-O may be any one among a blue light emitting element, a green light emitting element, or a red light emitting element, and the other light emitting elements may each be organic light emitting elements OED1-O and OED2-O. In the display layer EDL-Oa according to an embodiment, the protection layer PIL-a may be between the inorganic emission layer QEL of the inorganic light emitting element QED-O and the organic electron transport layer O-ETL. In FIG. 7B, the inorganic light emitting element QED-O, the first organic light emitting element OED1-O, and the second organic light emitting element OED2-O are shown to be arranged in that order, but the arrangement order is not limited thereto.

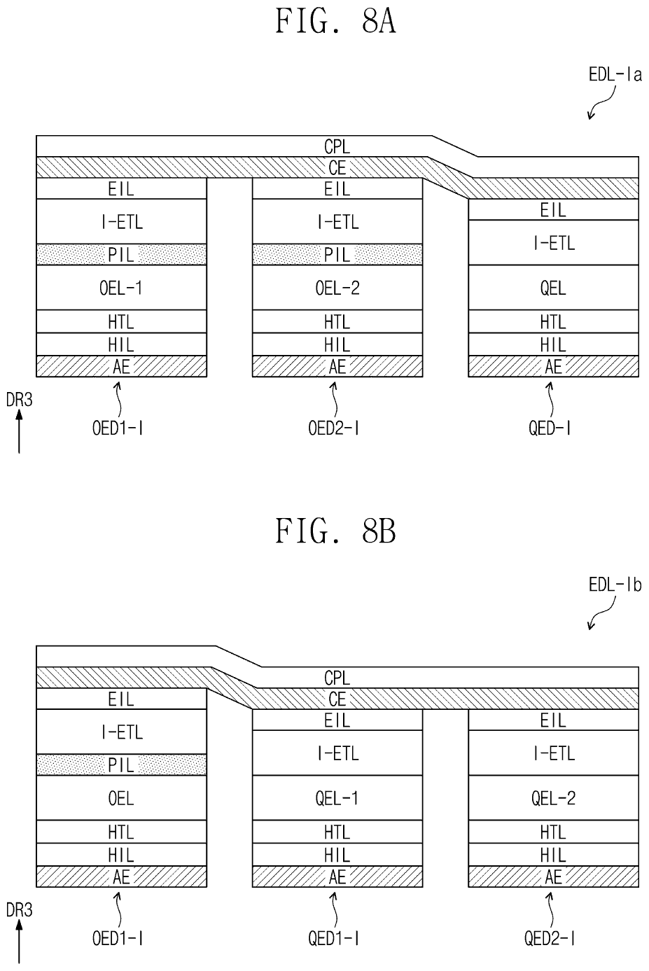

FIGS. 8A-8B correspond to a case where the display layers EDL-Ia and EDL-Ib each include an inorganic electron transport layer I-ETL.

The display layer EDL-la according to an embodiment shown in FIG. 8A may include two organic light emitting elements OED1-I and OED2-I and one inorganic light emitting element QED-I. In some embodiments, the inorganic light emitting element QED-I may be any one among a blue light emitting element, a green light emitting element, or a red light emitting element, and the other light emitting elements may each be organic light emitting elements OED1-I and OED2-I. In the display layer EDL-la according to an embodiment, the protection layer PIL may be between organic emission layers OEL-1 and OEL-2 of the organic light emitting elements OED1-I and OED2-I and the inorganic electron transport layer I-ETL. In FIG. 8A, the first organic light emitting element OED1-1, the second organic light emitting element OED2-I, and the inorganic light emitting element QED-I are shown to be arranged in that order, but the arrangement order is not limited to thereto.

The display layer EDL-Ib according to an embodiment shown in FIG. 8A may include two inorganic light emitting elements QED1-I and QED2-I and one organic light emitting element OED-I. In some embodiments, the organic light emitting element OED-I may be any one among a blue light emitting element, a green light emitting element, or a red light emitting element, and the other light emitting elements may each be inorganic light emitting elements QED1-I and QED2-1. In the display layer EDL-Ib according to an embodiment, the protection layer PIL may be between the organic emission layers OEL of the organic light emitting element OED-I and the inorganic electron transport layer I-ETL. In FIG. 8B, the organic light emitting element OED-I, the first inorganic light emitting element QED1-1, and the second inorganic light emitting element QED2-I are shown to be arranged in that order, but the arrangement order is not limited thereto.

The display device of an embodiment including the display layer according to an embodiment described with reference to FIGS. 7A-8B also includes a protection layer including a polar polymer between an organic emission layer and an inorganic electron transport layer, or between an inorganic emission layer and an organic electron transport layer in a light emitting element, and may thus exhibit excellent luminous efficiency and service life through improved interface properties.

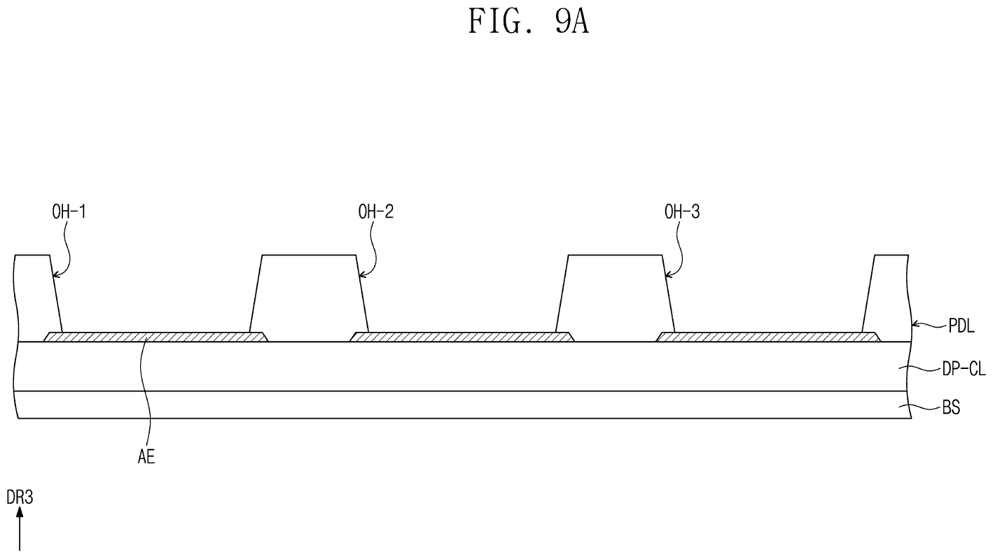

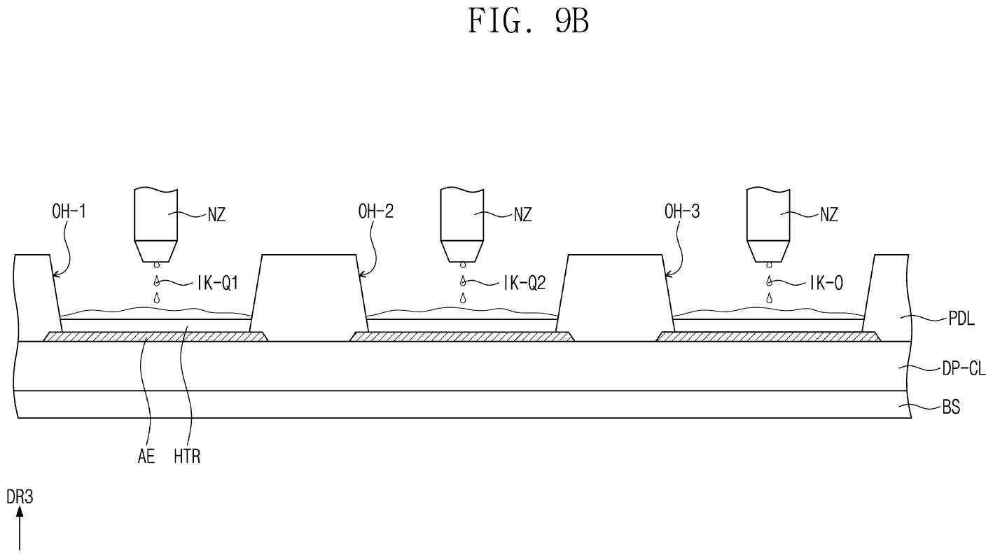

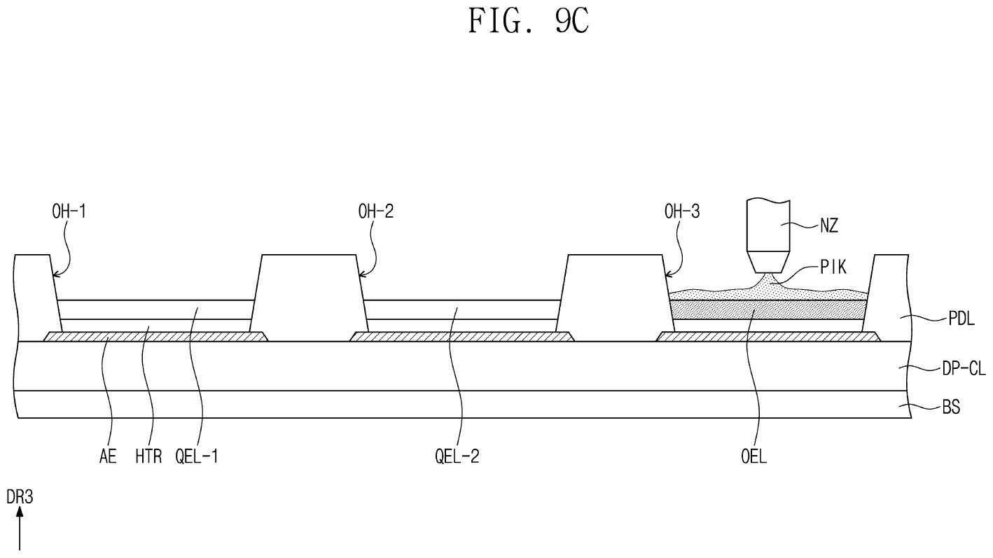

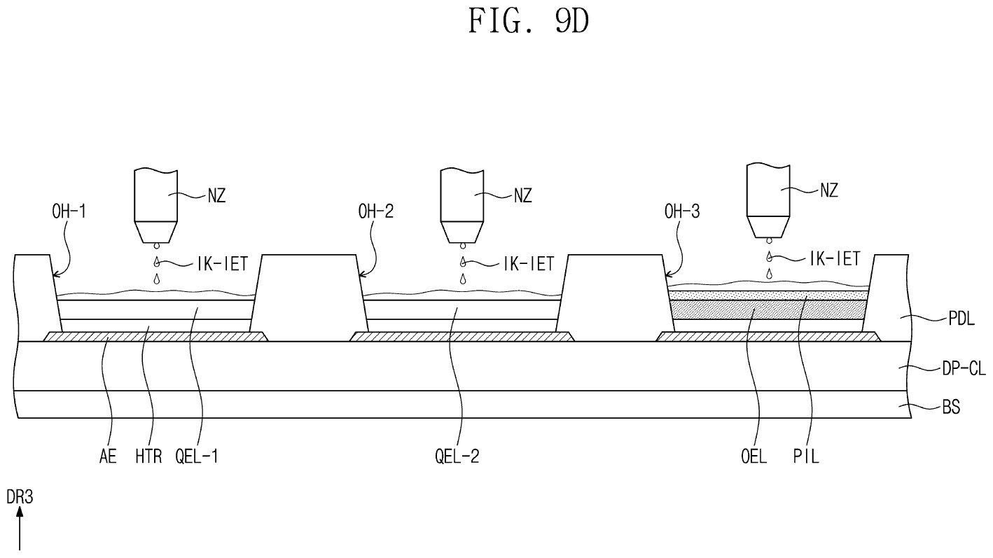

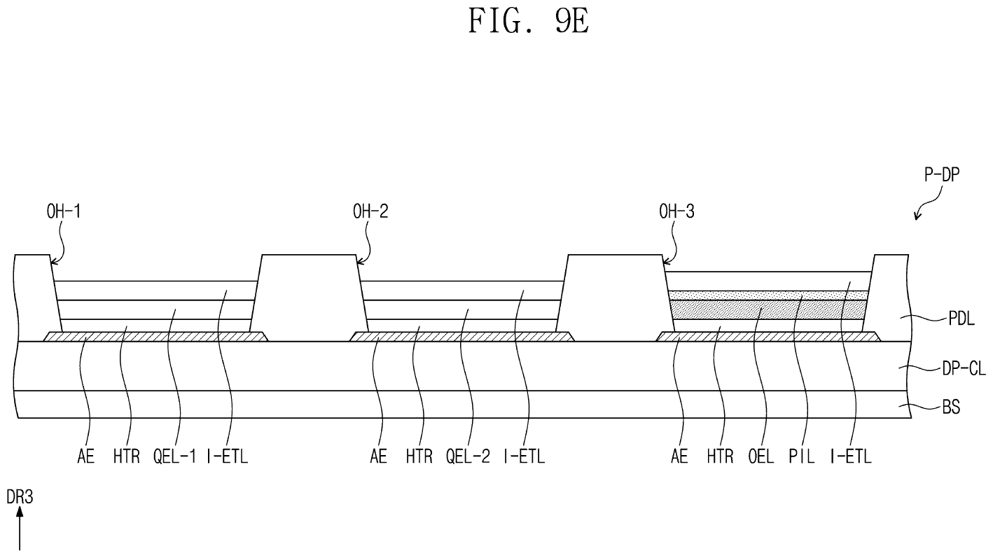

FIGS. 9A-9E each show a portion of a method for manufacturing a display device according to an embodiment.

The method for manufacturing a display device according to an embodiment may include forming a circuit layer on a base layer and forming a display layer including a pixel defining layer having a plurality of pixel openings defined on the circuit layer, and an inorganic light emitting element and an organic light emitting element, which are separated by the pixel defining layer. In some embodiments, the forming of the display layer may include sequentially providing a hole transport region, an inorganic emission layer including quantum dots, and an electron transport region in at least one of the pixel openings through a method of inkjet printing to form an inorganic light emitting element, and sequentially providing the hole transport region, an organic emission layer including an organic light emitting material, and the electron transport region in the other pixel openings through a method of inkjet printing to form an organic light emitting element.

In some embodiments, the forming of the inorganic light emitting element or the forming of the organic light emitting element may include providing a protection layer ink between the inorganic emission layer and the electron transport region or between the organic emission layer and the electron transport region through a method of inkjet printing to form a protection layer. In some embodiments, the protection layer ink may include a polar polymer and a polar organic solvent.

In some embodiments, the forming of the organic-inorganic light emitting elements and the forming of the organic light emitting element may not be performed sequentially, but the forming of the inorganic light emitting element and the hole transport region and the forming of the hole transport region of the inorganic light emitting element may be performed as a single process. In some embodiments, the forming of the inorganic light emitting element and the emission layer and the forming of the emission layer of the inorganic light emitting element may be performed in a single process, and the forming of the inorganic light emitting element and the electron transport region and the forming of the electron transport region of the inorganic light emitting element may be performed in a single process.

The hole transport regions of the inorganic light emitting element and the organic light emitting element may be formed in the same process before the provision of each emission layer by providing the same hole transport material, and also the electron transport regions of the inorganic light emitting element and the organic light emitting element may be formed in the same process after the provision of each emission layer by using the same electron transport material.

A display device manufactured by the method for manufacturing a display device of an embodiment described with reference to FIGS. 9A-9E, and the like may have the structure of the display device of an embodiment described with reference to FIGS. 1-8B, and the like. Accordingly, the contents described for the components of the display device of FIGS. 1-8B using the same reference numerals may also apply to each component of the display device shown in FIGS. 9A-9E.

One portion of the method for manufacturing a display device shown in FIGS. 9A-9E as an example may have the structure of the display device DD and the light emitting elements ED-R, ED-G, and ED-B described with reference to FIGS. 3 and 4C. This is presented as an example and may also apply to the structure of the display device described with reference to FIGS. 6-8B.

In the method for manufacturing a display device of an embodiment, a circuit layer DP-CL may be formed on the base layer BS and a pixel defining layer PDL may be formed on the circuit layer DP-CL. FIG. 9A shows one portion of forming a display layer including a pixel defining layer PDL in which a plurality of pixel openings OH-1, OH-2, and OH-3 are defined as an example.

Before forming the pixel defining layer PDL, the first electrode AE may be formed on the circuit layer DP-CL. The first electrode AE may be patterned on the circuit layer DP-CL. An upper surface of each of the first electrodes AE spaced apart may be exposed through each of the pixel openings OH-1, OH-2, and OH-3. An edge portion of the first electrode AE may partially overlap the pixel defining layer PDL.

Each of the pixel openings OH-1, OH-2, and OH-3 may correspond to each of the first to third light emitting regions PXA-R, PXA-G, and PXA-B described in FIG. 3.

FIG. 9B shows one portion of forming a display layer as an example. FIG. 9B shows forming the hole transport region HTR on the first electrode AE, and emission layer inks IK-Q1, IK-Q2, and IK-O are provided on the hole transport region HTR to form an emission layer.

In some embodiments, the hole transport region HTR may be formed by providing a hole transport material on the first electrode AE using an inkjet printing method.

The hole transport region HTR may be formed in the first pixel opening OH-1, and the first inorganic emission layer ink IK-Q1 including an inorganic luminous body may be provided on the hole transport region HTR. The first inorganic emission layer ink IK-Q1 may be provided through a nozzle NZ of the inkjet printing equipment.

The hole transport region HTR may be formed in the second pixel opening OH-2, and the second inorganic emission layer ink IK-Q2 including an inorganic luminous body may be provided on the hole transport region HTR. The second inorganic emission layer ink IK-Q2 may be provided through a nozzle NZ of the inkjet printing equipment.

The hole transport region HTR is formed in the third pixel opening OH-3, and the organic emission layer ink IK-O including an organic luminous body may be provided on the hole transport region HTR. The organic emission layer ink IK-O may be provided through a nozzle NZ of the inkjet printing equipment.

The first inorganic emission layer ink IK-Q1, the second inorganic emission layer ink IK-Q2, and the organic emission layer ink IK-O may each be provided in the pixel openings OH-1, OH-2, and OH-3 through a method of inkjet printing to form emission layer QEL-1, QEL-2, and OEL. The first inorganic emission layer ink IK-Q1 and the second inorganic emission layer ink IK-Q2 may each contain quantum dots, which are inorganic luminous bodies, and the organic emission layer ink IK-O may contain a light emitting dopant, which is an organic luminous body.

FIG. 9C is a view showing providing a protection layer ink to form a protection layer. Referring to FIG. 9C, the first inorganic emission layer QEL-1 may be formed in the first pixel opening OH-1, the second inorganic emission layer QEL-2 may be formed in the second pixel opening OH-2, and the organic emission layer OEL may be formed in the third pixel opening OH-3. The first and second inorganic emission layers QEL-1 and QEL-2 and the organic emission layer OEL may each be formed using an inkjet printing method.

In the method for manufacturing a display device according to an embodiment, the protection layer ink PIK may be provided on the organic emission layer OEL. The protection layer ink PIK may be provided through the nozzle NZ of the inkjet printing equipment. The protection layer ink PIK may contain a polar polymer and a polar organic solvent.

For example, the protection layer ink PIK may be a polar polymer and include poly(ethylene glycol), poly(4-vinylpyridine), polyvinylpyrrolidone, and/or polyethylenimine. In some embodiments, the protection layer ink PIK may include dimethyl sulfoxide, ethylene glycol, and/or an ether-based solvent as a polar organic solvent.

In an embodiment, the polar polymer included in the protection layer ink PIK may be highly soluble in a polar organic solvent.

The protection layer ink PIK is prepared to contain a polar organic solvent, so that the viscosity thereof may be adjusted to facilitate the use thereof in the inkjet printing equipment, and may be easily ejected in a set or fixed amount at a volume set at the nozzle NZ, and/or the like. In some embodiments, when water is used as a solvent, the protection layer ink PIK is not easily ejected from the nozzle NZ due to the high surface tension of water, but with the use of a polar organic solvent, the protection layer ink PIK may be easily ejected from an ejection portion of the nozzle NZ. It may be easily discharged without being formed. For example, the protection layer ink PIK may be easily discharged without or substantially without clogging the nozzle NZ. Accordingly, the protection layer ink PIK may maintain excellent application properties.

FIG. 9D shows forming an electron transport layer through an inkjet printing method as an example. FIG. 9D shows providing an inorganic electron transport material IK-IET to form an electron transport layer.

The inorganic electron transport material IK-IET may be provided directly on the first inorganic emission layer QEL-1, the second inorganic emission layer QEL-2, and the protection layer PIL. The inorganic electron transport material IK-IET may be provided on each of the first inorganic emission layer QEL-1 and the second inorganic emission layer QEL-2 in the first pixel opening OH-1 and the second pixel opening OH-2, and the inorganic electron transport material IK-IET may be provided on the protection layer PIL in the third pixel opening OH-3.

The same inorganic electron transport material IK-IET may be provided corresponding to the first to third pixel openings OH-1, OH-2, and OH-3. In some embodiments, the same electron transport material IK-IET is provided on the inorganic emission layer QEL-1 and QEL-2 and the organic emission layer OEL having different light emitting material properties in a single process, and accordingly, the issue of reduction in process productivity that takes place when the electron transport material is altered depending on the material properties of the emission layer may be improved.

In some embodiments, the method for manufacturing a display device of an embodiment includes forming the protection layer PIL on the organic emission layer OEL to provide the same electron transport material IK-IET on the inorganic emission layer QEL-1 and QEL-2 and the organic emission layer OEL through a single process, thereby achieving excellent process productivity effects.

FIG. 9E shows a preliminary display panel P-DP formed through the method of FIGS. 9A-9D. The preliminary display panel P-DP may include the hole transport region HTR, the inorganic emission layer QEL-1 and QEL-2, and the inorganic electron transport layer I-ETL, which are sequentially provided in the first and second pixel openings OH-1 and OH-2 and formed through inkjet printing, and the hole transport region HTR, the organic emission layer OEL, the protection layer PIL, and then inorganic electron transport layer I-ETL, which are sequentially disposed in the third pixel opening OH-3 and formed through inkjet printing.

The preliminary display panel P-DP represents one portion of the method for manufacturing a display device, and then additionally, the second electrode CE (FIG. 3), the capping layer CPL (FIG. 3), and the encapsulation layer TFE may be sequentially provided on the inorganic electron transport layer I-ETL to manufacture the display panel DP (FIG. 3).

In some embodiments, unlike what was described with reference to FIGS. 9A-9E, the electron transport layer may be formed as an organic electron transport layer by providing an organic electron transport material, and in some embodiments, in the forming of the inorganic light emitting element including the inorganic emission layer among the light emitting elements, the forming of a protection layer may be performed before the forming of the emission layer and forming of the organic electron transport layer.

The method for manufacturing a display device of an embodiment includes forming a protection layer using a protection layer ink including a polar polymer between the emission layer and the electron transport layer in any one of the forming of the inorganic light emitting element and the forming of the organic light emitting element, and may thus provide a display device having excellent luminous efficiency. In some embodiments, the method for manufacturing a display device of an embodiment includes forming a protection layer using a protection layer ink including a polar polymer between the emission layer and the electron transport layer in any one of the forming of the inorganic light emitting element and the forming of the organic light emitting element to provide the same electron transport material in the forming of the inorganic light emitting element and the forming of the organic light emitting element so as to form an electron transport layer, thereby achieving excellent process productivity.

Hereinafter, the results of evaluating the properties of a light emitting element according to an embodiment included in a display device of an embodiment will be described with reference to Examples and Comparative Examples. The Examples and Comparative Examples below are provided only for the understanding of the subject matter of the present disclosure, and the scope of the present disclosure is not limited thereto.

### Manufacture of Light Emitting Elements

The light emitting elements of Comparative Example 1 and Example 1 correspond to light emitting elements that emit green light. The light emitting elements of Comparative Example 1 and Example 1 differ in the presence or absence of a protection layer.

An ITO glass substrate (15 Ω/cm²) from Corning was cut into a size of 50 mm×50 mm×0.7 mm and then subjected to ultrasonic cleaning in isopropyl alcohol and pure water each for 30 minutes to prepare a first electrode. A hole injection layer, a hole transport layer, an emission layer, and an electron transport layer were sequentially formed on the first electrode. Hole injection layers, hole transport layers, emission layers, and electron transport layers of Comparative Examples and Examples for evaluating light emitting elements were each formed using a spin coating method.

Specifically, the cleaned first electrode was spin-coated with PEDOT/PSS (a weight ratio of 5:5) to form a 60 nm thick film, and then the resulting product was baked at 200° C. for 30 minutes to form a hole injection layer. The hole injection layer was spin-coated with poly[(9,9-dioctylfluorenyl-2,7-diyl)-alt(4,4′-(N-(4-butylphenyl)))] (TFB) to form a 20 nm thick film, and then the resulting product was baked at 240° C. for 10 minutes to form a hole transport layer.

The hole transport layer was spin-coated with an emission layer composition to form a 30 nm thick film, and then the resulting product was baked at 140° C. for 10 minutes to form an emission layer. The emission layer was formed of quantum dots having a core of InP and a shell of ZnS.

Then, in Comparative Example 1, the emission layer was spin-coated with an electron transport layer composition to form a 20 nm thick electron transport layer. The electron transport layer was formed from an organic electron transport material of OET-1 below.

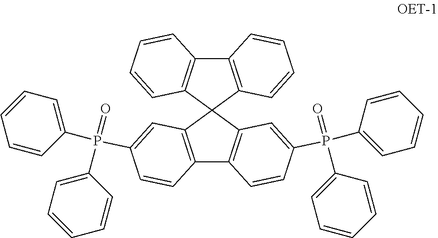 [SMILES: O=P(c1ccccc1)(c1ccccc1)c1ccc2c(c1)C1(c3ccccc3-c3ccccc31)c1cc(P(=O)(c3ccccc3)c3ccccc3)ccc1-2]

Then, the electron transport layer was vacuum deposited with Al to form a 100 nm thick second electrode to manufacture a light emitting element of Comparative Example 1.

In the light emitting element of Example 1, a 10 nm thick film was formed with polyethyleneimine on the emission layer formed of quantum dots having a core of InP and a shell of ZnS, and then the film was baked at 140° C. for 10 minutes to form a protection layer. Unlike Comparative Example 1, the electron transport layer formed of OET-1 on the protection layer after the forming of the protection layer and the second electrode were sequentially formed to manufacture Example 1.

The light emitting elements of Comparative Example 2 and Example 2 correspond to light emitting elements that emit blue light. The light emitting elements of Comparative Example 2 and Example 2 differ in the presence or absence of a protection layer.

An ITO glass substrate (15 Ω/cm²) from Corning was cut into a size of 50 mm×50 mm×0.7 mm and then subjected to ultrasonic cleaning in isopropyl alcohol and pure water each for 30 minutes to prepare a first electrode. A hole injection layer, a hole transport layer, an emission layer, and an electron transport layer were sequentially formed on the first electrode. Hole injection layers, hole transport layers, emission layers, and electron transport layers of Comparative Examples and Examples for evaluating light emitting elements were each formed using a spin coating method.

Specifically, the cleaned first electrode was spin-coated with PEDOT/PSS (a weight ratio of 5:5) to form a 60 nm thick film, and then the resulting product was baked at 200° C. for 30 minutes to form a hole injection layer. The hole injection layer was spin-coated with TFB to form a 20 nm thick film, and then the resulting product was baked at 240° C. for 10 minutes to form a hole transport layer.

The hole transport layer was spin-coated with an emission layer composition to form a 30 nm thick film, and then the resulting product was baked at 140° C. for 10 minutes to form an emission layer.

The blue host material and the blue dopant material used to form the emission layer in Comparative Example 2 and Example 2 are as follows.

### Blue Host Material

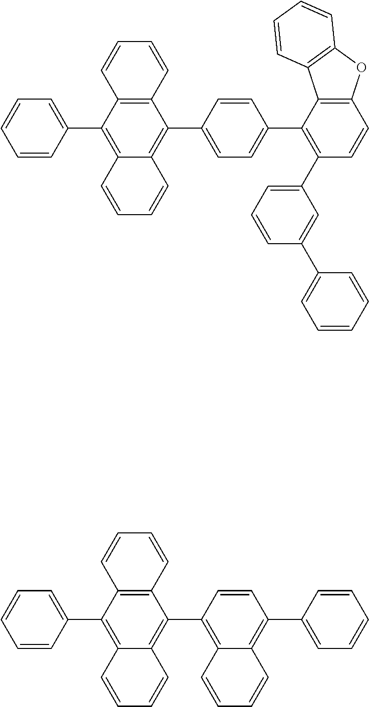

### Blue Dopant Material

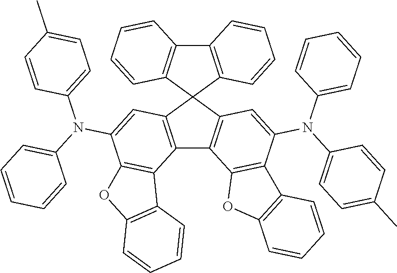 [SMILES: Cc1ccc(N(c2ccccc2)c2cc3c(c4c2oc2ccccc24)-c2c(cc(N(c4ccccc4)c4ccc(C)cc4)c4c2oc2ccccc24)C32c3ccccc3-c3ccccc32)cc1]

Then, in Comparative Example 2, the emission layer was spin-coated with an electron transport layer composition to form a 20 nm thick electron transport layer. The electron transport layer was formed of ZnMgO. Then, the electron transport layer was vacuum deposited with Al to form a 100 nm thick second electrode to manufacture a light emitting element of Comparative Example 2.

In the light emitting element of Example 2, a 10 nm thick film was formed with polyethyleneimine on the emission layer, and then the film was baked at 140° C. for 10 minutes to form a protection layer. Unlike Comparative Example 2, in Example 2, the electron transport layer was formed of ZnMgO on the protection layer after the forming of the protection layer, Thereafter, a second electrode was sequentially formed on the electron transport layer.

In the manufacture of the light emitting elements of Comparative Examples and Examples, a Suicel plus 200 deposition machine from Sunic System was used to deposit the second electrode.

In addition, driving voltage, luminous efficiency, and color coordinates of the light emitting elements of the Comparative Examples and Examples were measured using Keithley SMU 236 and a luminance meter PR650.

Table 1 shows the results of evaluating the light emitting elements of the Comparative Examples and Examples.

TABLE 1

| | Driving | Luminous | Color | Color |
|---|---|---|---|---|
| | voltage | efficiency | coordinate | coordinate |
| Item | (V) | (cd/A) | CIEx | CIEy |
| Com- | 8.5 | 6.8 | 0.278 | 0.703 |
| parative | | | | |
| Example | | | | |
| 1 | | | | |
| Example | 9.9 | 41.5 | 0.294 | 0.691 |
| 1 | | | | |
| Com- | 4.8 | 0.4 | 0.139 | 0.044 |
| parative | | | | |
| Example | | | | |
| 2 | | | | |
| Example | 4.9 | 3.5 | 0.139 | 0.046 |
| 2 | | | | |

Comparing Comparative Example 1 with Example 1, it is seen that the driving voltage was partially increased in Example 1, but the luminous efficiency was significantly improved. In addition, from the color coordinates showing similar values, it is seen that Example 1 introducing the protection layer exhibits similar optical properties and significantly improved luminous efficiency compared to Comparative Example 1. Comparing Comparative Example 2 with Example 2, it is seen that Example 2 shows the driving voltage similar to that of Comparative Example 2 and has significantly improved luminous efficiency. In addition, from the color coordinates showing similar values, it is seen that Example 2 introducing the protection layer exhibits similar optical properties and significantly improved luminous efficiency compared to Comparative Example 2.

That is, in the case of Comparative Example 1 and Example 1 including an inorganic emission layer and an organic electron transport layer as a light emitting element component, it is seen that excellent luminous efficiency is achieved by including a protection layer including a polar polymer between the inorganic emission layer and the organic electron transport layer. In addition, in the case of Comparative Example 2 and Example 2 including an organic emission layer and an inorganic electron transport layer as a light emitting element component, it is seen that excellent luminous efficiency is achieved by including a protection layer including a polar polymer between the organic emission layer and the inorganic electron transport layer.

A display device of an embodiment may include both an inorganic light emitting element and an organic light emitting element, include the same electron transport layer in the inorganic light emitting element and the organic light emitting element, and include a protection layer formed of a polar polymer between the emission layer of the inorganic light emitting element or the organic light emitting element and the electron transport layer. Accordingly, an issue of quenching caused by differences in material properties between the organic emission layer and the inorganic electron transport layer, or between the inorganic emission layer and the organic electron transport layer is improved, and thus the display device may exhibit excellent luminous efficiency and display quality.

A method for manufacturing a display device of an embodiment includes forming a protection layer between an emission layer and an electron transport layer in one of forming an inorganic light emitting element and forming an organic light emitting element to provide the same electron transport material to both the inorganic light emitting element and the organic light emitting element through the same manufacturing method as a single process, thereby exhibiting excellent productivity. In addition, the method for manufacturing a display device of an embodiment includes forming a protection layer between an emission layer and an electron transport layer in one of forming an inorganic light emitting element and forming an organic light emitting element to improve quenching caused by differences in material properties between the emission layer and the electron transport layer, and may thus provide a display device having improved luminous efficiency.

When a display device of an embodiment includes both an organic light emitting element and an inorganic light emitting element, which have different emission layer material characteristics, the same electron transport material is provided between an emission layer and an electron transport layer and thus is provided on the emission layer, and accordingly, the display device of an embodiment may exhibit excellent light efficiency.

A display device of an embodiment includes a protection layer between an emission layer and an electron transport layer, which have different material properties as an organic layer and an inorganic layer to improve quenching properties in the emission layer according to differences in material properties between the emission layer and the electron transport layer, and may thus exhibit excellent luminous efficiency.

A display device of an embodiment provides an electron transport material of the same material on each emission layer of an organic light emitting element and an inorganic light emitting element, and may thus exhibit excellent processability, and may be used to manufacture a display device having excellent luminous efficiency in both the organic light emitting element and the inorganic light emitting element.

Although the subject matter of the present disclosure has been described with reference to example embodiments of the present disclosure, it will be understood that the subject matter of the present disclosure should not be limited to these example embodiments but various changes and modifications may be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A display device comprising:
a base layer;
a circuit layer on the base layer;
a pixel defining layer on the circuit layer and having a plurality of pixel openings defined therein; and
a plurality of light emitting elements each comprising a hole transport region, an emission layer, and an electron transport region which are sequentially stacked, and on the circuit layer,
wherein the light emitting elements comprise:
an inorganic light emitting element comprising an inorganic luminous body in the emission layer; and
an organic light emitting element comprising an organic luminous body in the emission layer, and
the inorganic light emitting element or the organic light emitting element comprises a protection layer between the emission layer and the electron transport region and comprising a polar polymer.

2. The display device of claim 1, wherein the protection layer comprises poly(ethylene glycol), poly(4-vinylpyridine), polyvinylpyrrolidone, and/or polyethylenimine.

3. The display device of claim 1, wherein the polar polymer is soluble in a polar organic solvent.

4. The display device of claim 3, wherein the polar organic solvent comprises dimethyl sulfoxide, ethylene glycol, and/or an ether-based solvent.

5. The display device of claim 1, wherein the protection layer has a thickness of about 50 Å to about 200 Å, and
the thickness of the protection layer is a distance from an uppermost portion of the emission layer of the inorganic light emitting element or the organic light emitting element comprising the protection layer to the electron transport region.

6. The display device of claim 1, wherein the electron transport region comprises an inorganic electron transport material, and the organic light emitting element comprises the protection layer.

7. The display device of claim 6, wherein the electron transport region comprises an electron transport layer comprising the inorganic electron transport material,
in the inorganic light emitting element, the electron transport layer is directly on the emission layer, and
in the organic light emitting element, the protection layer is directly between the electron transport layer and the emission layer.

8. The display device of claim 1, wherein the electron transport region comprises an organic electron transport material, and the inorganic light emitting element comprises the protection layer.

9. The display device of claim 8, wherein the electron transport region comprises an electron transport layer comprising the organic electron transport material,
in the organic light emitting element, the electron transport layer is directly on the emission layer, and
in the inorganic light emitting element, the protection layer is directly between the electron transport layer and the emission layer.

10. The display device of claim 8, wherein the inorganic luminous body comprises a plurality of quantum dots, and
the protection layer of the inorganic light emitting element is in an upper portion of the emission layer and permeates between the quantum dots.

11. The display device of claim 1, wherein the hole transport region, the emission layer, and the electron transport region are stacked and provided in each of the pixel openings, and
the hole transport regions included in the inorganic light emitting element and the organic light emitting element are the same, and the electron transport regions included in the inorganic light emitting element and the organic light emitting element are the same.

12. A display device comprising a red light emitting region, a green light emitting region, and a blue light emitting region, which are distinct from one another when viewed on a plane,
the display device comprising:
a base layer;
a circuit layer on the base layer; and
a display layer comprising a red light emitting element corresponding to the red light emitting region, a green light emitting element corresponding to the green light emitting region, and a blue light emitting element corresponding to the blue light emitting region, and on the circuit layer,
wherein the red light emitting element, the green light emitting element, and the blue light emitting element each comprise a hole transport region, an emission layer, and an electron transport region which are sequentially stacked,
one or two of the light emitting elements selected from the red light emitting element, the green light emitting element, and the blue light emitting element are inorganic light emitting elements comprising quantum dots in the emission layer, and the other light emitting elements are organic light emitting elements comprising an organic light emitting material in the emission layer, and
the inorganic light emitting element or the organic light emitting element comprises a protection layer between the emission layer and the electron transport region and comprising a polar polymer.

13. The display device of claim 12, wherein the protection layer comprises poly(ethylene glycol), poly(4-vinylpyridine), polyvinylpyrrolidone, and/or polyethylenimine.

14. The display device of claim 12, wherein the electron transport region of the inorganic light emitting element and the organic light emitting element comprises an inorganic electron transport layer comprising an inorganic electron transport material, and
the protection layer is directly between the emission layer of the organic light emitting element and the inorganic electron transport layer.

15. The display device of claim 12, wherein the electron transport region of the inorganic light emitting element and the organic light emitting element comprises an organic electron transport layer comprising an organic electron transport material, and
the protection layer is directly between the emission layer of the inorganic light emitting element and the organic electron transport layer.

16. The display device of claim 12, wherein the red light emitting element and the green light emitting element are the inorganic light emitting element, and the blue light emitting element is the organic light emitting element.

17. A method for manufacturing a display device, the method comprising:
forming a circuit layer on a base layer; and
forming a display layer comprising a pixel defining layer having a plurality of pixel openings defined on the circuit layer, and an inorganic light emitting element and an organic light emitting element which are separated by the pixel defining layer,
wherein the forming of the display layer comprises:
sequentially providing a hole transport region, an inorganic emission layer including quantum dots, and an electron transport region in at least one of the pixel openings through a method of inkjet printing to form the inorganic light emitting element; and
sequentially providing the hole transport region, an organic emission layer comprising an organic light emitting material, and the electron transport region in the other pixel openings through a method of inkjet printing to form the organic light emitting element, and
the forming of the inorganic light emitting element or the forming of the organic light emitting element includes providing a protection layer ink between the inorganic emission layer and the electron transport region or between the organic emission layer and the electron transport region through a method of inkjet printing to form a protection layer, and the protection layer ink comprises a polar polymer and a polar organic solvent.

18. The method of claim 17, wherein the polar polymer comprises poly(ethylene glycol), poly(4-vinylpyridine), polyvinylpyrrolidone, and/or polyethylenimine.

19. The method of claim 17, wherein the polar organic solvent comprises dimethyl sulfoxide, ethylene glycol, and/or an ether-based solvent.

20. The method of claim 17, wherein the electron transport region formed in the forming of the inorganic light emitting element and the forming the organic light emitting element comprises an electron transport layer formed using the same electron transport material.

21. The method of claim 20, wherein the electron transport material comprises an organic electron transport material, and
the forming of the inorganic light emitting element comprises forming the protection layer between the inorganic emission layer and the electron transport layer.

22. The method of claim 20, wherein the electron transport material comprises an inorganic electron transport material, and
the forming of the organic light emitting element comprises forming the protection layer between the organic emission layer and the electron transport layer.
